(19) United States
(12) Patent Application Publication
(10) Pub. No.: US 2025/0098099 A1
(43) Pub. Date: Mar. 20, 2025

(54) Electrical Module of Modular Electrical Panelboard

(71) Applicant: Span.IO, Inc., San Franciscon, CA (US)

(72) Inventors: Nicholas Reid, San Francisco, CA (US); Ryan Carter Kroeze, San Francisco, CA (US); Venkatraghavan Sundararajna, San Francisco, CA (US); Anna Lai, Stanford, CA (US); Cole Hamilton Ashman, San Francisco, CA (US); Hans Von Clemm, San Francisco, CA (US); Ian Casimir Dimen, Berkeley, CA (US); Michael Motola-Barnes, San Francisco, CA (US); Irene Yang, San Francisco, CA (US); Christopher William Ledesma, San Francisco, CA (US)

(21) Appl. No.: 18/886,812

(22) Filed: Sep. 16, 2024

Related U.S. Application Data
(63) Continuation-in-part of application No. 18/586,362, filed on Feb. 23, 2024.
(60) Provisional application No. 63/551,192, filed on Feb. 8, 2024.
(60) Provisional application No. 63/583,141, filed on Sep. 15, 2023.

(51) Int. Cl. H05K 7/14; H02B 1/21; H05K 7/20

(52) U.S. Cl. CPC H05K 7/1489; H02B 1/21; H05K 7/1457; H05K 7/1492; H05K 7/20718

(57) ABSTRACT

Some embodiments relate to a chassis module for a chassis, the chassis module includes an insertion element configured to slide into one of a plurality of receiving compartments of a spine of the chassis. The insertion element includes a first electrical contact and a second electrical contact. The first electrical contact is on a first side of the insertion element and is configured to physically contact a first bus bar of the spine. The second electrical contact is on a second side of the insertion element opposite the first side. The second electrical contact is configured to contact a second bus bar of the spine.

### CROSS-REFERENCE TO RELATED APPLICATION(S)

This application is a continuation-in-part of U.S. patent application Ser. No. 18/586,362, “Modular Electrical Panelboard” filed on Feb. 23, 2024 which claims the benefit of and priority to U.S. Provisional Patent Application Ser. No. 63/583,141, “Electrical Panel Construction,” filed on Sep. 15, 2023 and U.S. Provisional Patent Application Ser. No. 63/551, 192, “Electrical Panel Construction,” filed on Feb. 8, 2024, each of which is incorporated herein by reference in its entirety.

### BACKGROUND

### 1. Technical Field

This disclosure relates generally to modular chassis (e.g., modular electrical panels) and chassis modules (e.g., electrical components) for the modular chassis.

### 2. Description of Related Art

Continued electrification will add massive amounts of demand to electrical distribution. Estimates are that net distribution capacity in the U.S. will increase by two to three times to support fully renewable energy sources. The current distribution system and site-level (e.g., building) wiring are not well instrumented and not easily controllable. They are not well suited to implement sophisticated energy management.

Furthermore, many electrical panels for buildings (e.g., residential homes) are bulky, costly, and difficult to install, repair, replace, and upgrade.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIGS. 1A-1C are diagrams illustrating front views of an example modular electrical panel.

FIG. 2 is a perspective diagram of the electrical panel with a different arrangement of electrical modules.

FIG. 3 is a perspective diagram of an example enclosure of the electrical panel.

FIG. 4 is a perspective diagram of an example spine of the electrical panel.

FIGS. 5A-B are diagrams of an example mains module.

FIGS. 6A-D are diagrams of an example branch module.

FIGS. 7A-B are diagrams of an example PCM (panel control module).

FIG. 7C is a perspective diagram of an example fan module that fits into the PCM.

FIG. 8 is a perspective diagram of an example gateway module.

FIGS. 9A-D are diagrams of an example lug module.

FIG. 9E is a diagram illustrating example lug module receiving compartments of the spine.

FIG. 9F is an exploded view diagram of the example lug module.

FIG. 10A is a diagram of a front perspective view of a second example spine of the electrical panel.

FIG. 10B is a diagram of a rear perspective view of the second example spine of the electrical panel.

FIG. 11 is a perspective diagram of a second example mains module.

FIGS. 12A-12F are diagrams of an example gateway and PCM.

FIG. 13 includes diagrams of example mounting locations for modules and of example field installable fasteners.

FIG. 14 is a diagram of example heat stake insert connections to fasten the L1/L2 to a spine.

FIG. 15 is a diagram of an example panel.

FIG. 16 is a diagram of an example module with several layers of heat sink material.

FIG. 17 is a diagram of example gaps in a spine for heat sink material.

FIG. 18 is a diagram of an example panel with 1.5″ receiving compartment.

FIG. 19 is a diagram of an example lug module that can fit in the 1.5″ a module slot of FIG. 18.

FIG. 20 is a diagram of an example stab coupled to a relay.

FIGS. 21-22 are diagrams of example gap pads to help with thermal management.

FIGS. 23-25 are diagrams of example fins to help with thermal management.

FIG. 26 is a diagram of an example clip that attaches to a stab.

FIGS. 27-28 are diagrams of an example branch module dead front.

FIG. 29 is a diagram of an example indicator on the front of a panel.

FIG. 30 is a diagram of example light pipes in a branch module.

FIG. 31 is a diagram of example light pipe structures with fins to direct airflow in an air duct of a branch module.

FIG. 32 is a diagram of an example heat spreader in a branch module.

FIGS. 33-35 are diagrams of example neutral blocks on a panel.

FIG. 36 is a diagram of an example user interface bar on a panel.

FIG. 37 is a diagram of an example gateway module and an example receiving compartment on top of a PCM.

FIGS. 38-39 are diagrams of an example antenna in a gateway module.

FIG. 40 is a diagram of an example antenna in a gateway module in a panel.

FIG. 41 is a diagram of an example PCM module.

FIG. 42 is a diagram illustrating example configurations for main breakers and Microgrid Interconnection Devices (MIDs).

FIG. 43 is a diagram of an example electrical panel.

FIGS. 44-45 are diagrams of example heat sink arrangements.

FIG. 46 illustrates example deadfront surface panels.

### DETAILED DESCRIPTION

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

### Introduction

As previously mentioned, conventional electrical panels on buildings (e.g., residential homes) are bulky, costly, and difficult to install, repair, replace, and upgrade. The present disclosure overcomes these limitations by describing modular electrical panels with modular electrical components (also referred to as “electrical modules,” “chassis modules,” “modules,” or “electrical panel components”). These provide many advantages to installers and building owners: (1) the modular electrical panel can be rightsized for the usage needs of each building. For example, if a building will only use 16 branch circuits, the panel can be installed with just 16 branch circuits (e.g., instead of a larger number of circuits on a conventional preset panel), thus saving the building owner money. Additionally, an installer no longer needs to guess which components will be needed for a given building before arriving at the installation site. (2) The modular electrical components can be installed on many different types of electrical panels (e.g., used in different application settings). (3) The modular electrical components can be mass produced (since the same set of modules can be installed on many different types of electrical panels). (4) Individual modular electrical components are easily accessible and can be easily replaced on site without an installer removing large portions of the panel (e.g., without removing adjacent modules). (5) Modular electrical components on an electrical panel can be individually upgraded (e.g., with additional functionalities) without the replacing or upgrading the entire electrical panel (or large portions of the panel). Example modular electrical panels and modular electrical components that provide one or more of the above advantages are further described below.

### Example Modular Electrical Panels

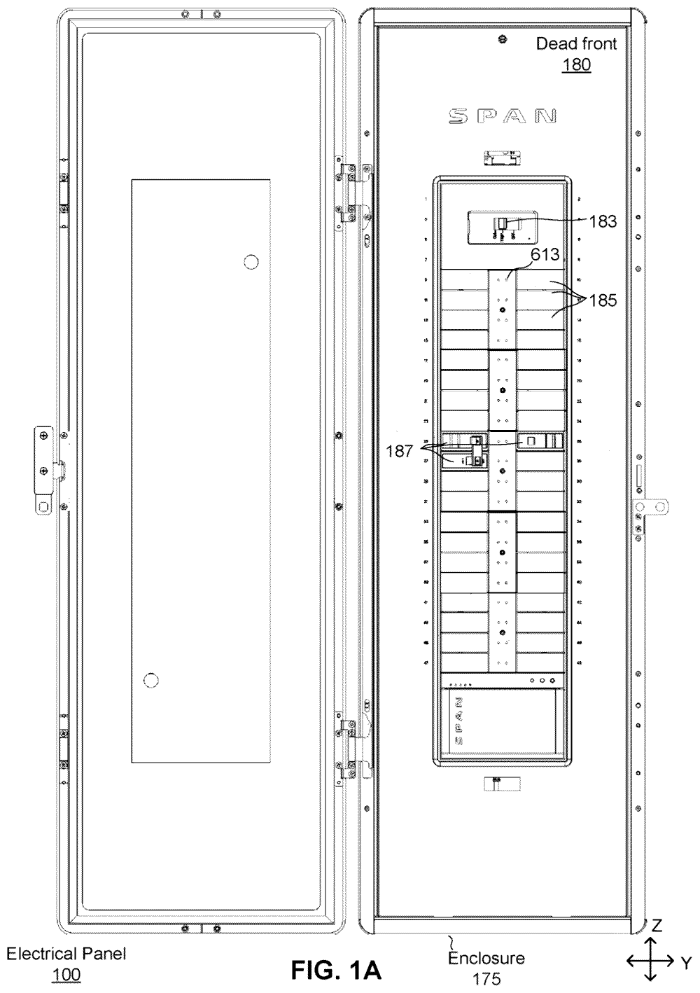

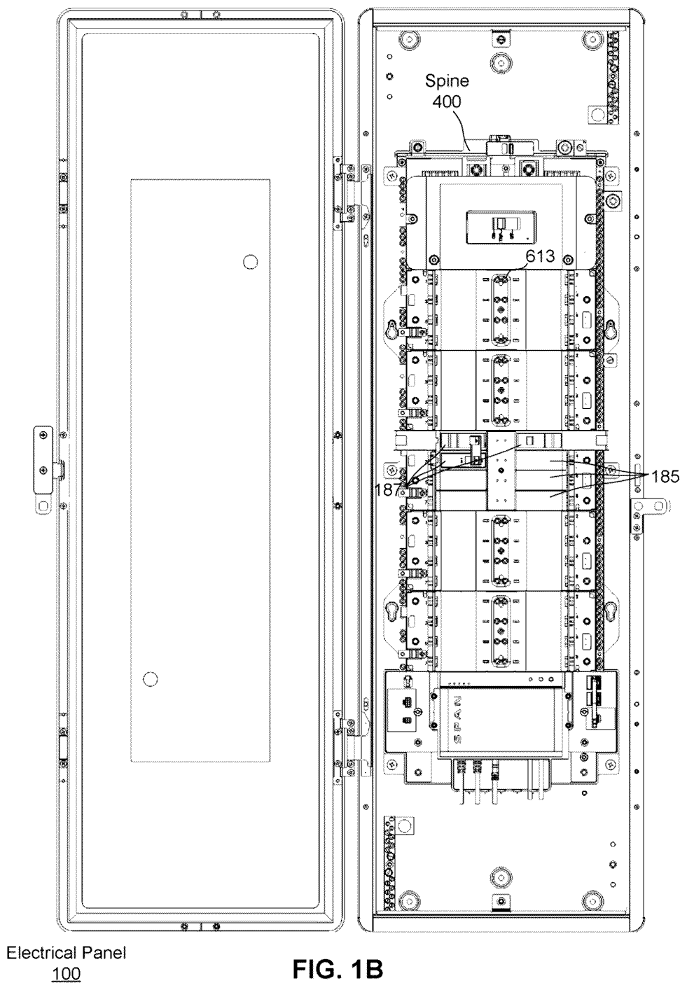

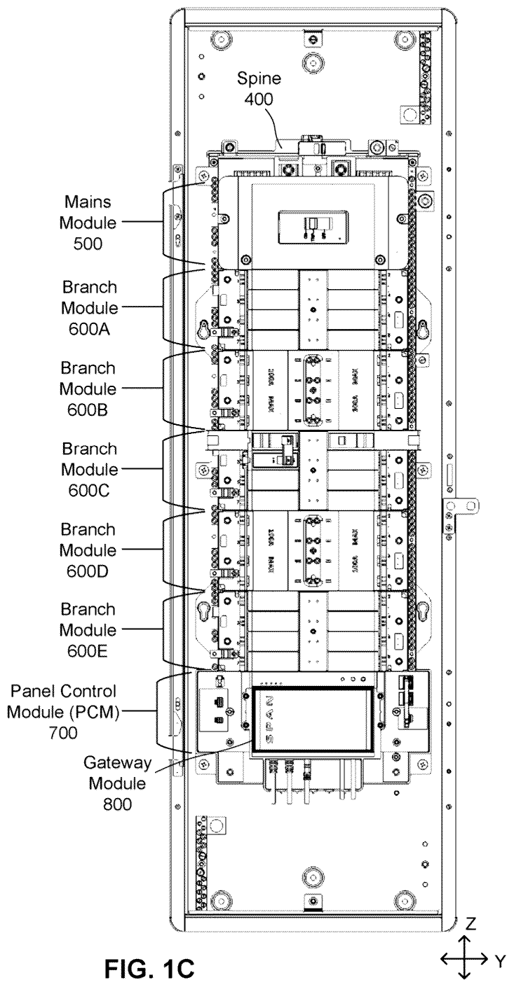

FIGS. 1A-1D are diagrams illustrating front views of a physical embodiment of a modular electrical panel 100. FIG. 1A is an end user's view of the panel 100. In the end user view, most of the electrical components are not physically accessible because they are hidden in an enclosure 175, under a dead front panel 180, and under modular dead front panels 185 (although the main breaker switch 183 and switches for three overcurrent circuit breakers 187 are accessible). FIG. 1B is a view of the electrical panel 100 with the dead front panel 180 removed and many of the modular dead front panels 185 removed. FIG. 1B illustrates various electrical component modules installed in a spine 400. FIG. 1C is a similar to FIG. 1B, except the door of the enclosure 175 is removed and labels are added to the electrical modules. Specifically, in the example of FIG. 1C, the panel 100 includes (from top to bottom) a mains module 500, five branch modules (labeled 600A-E), a panel control module (PCM) 700, and a gateway module 800.

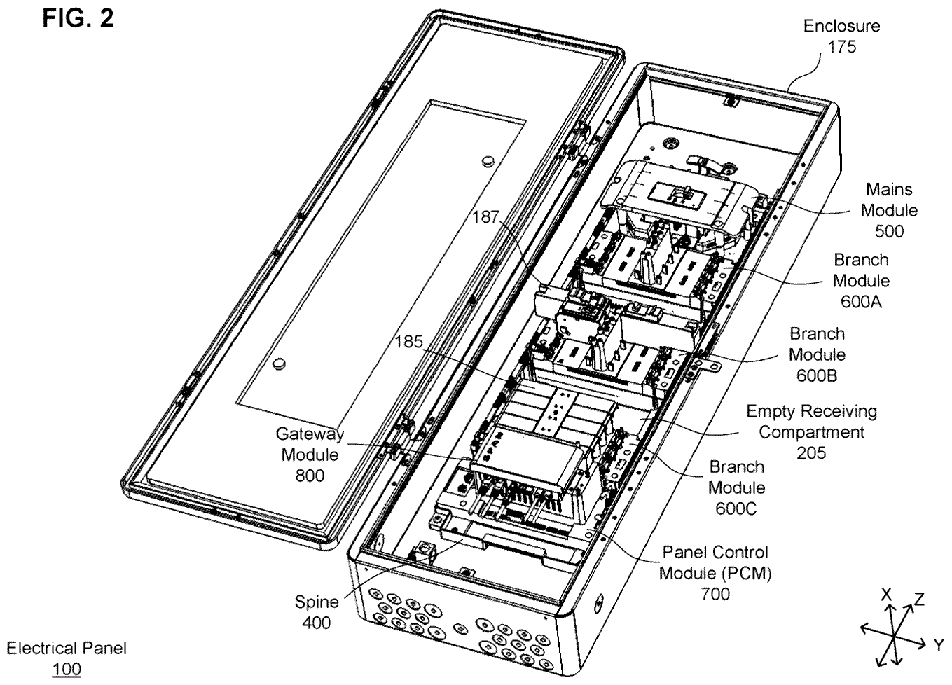

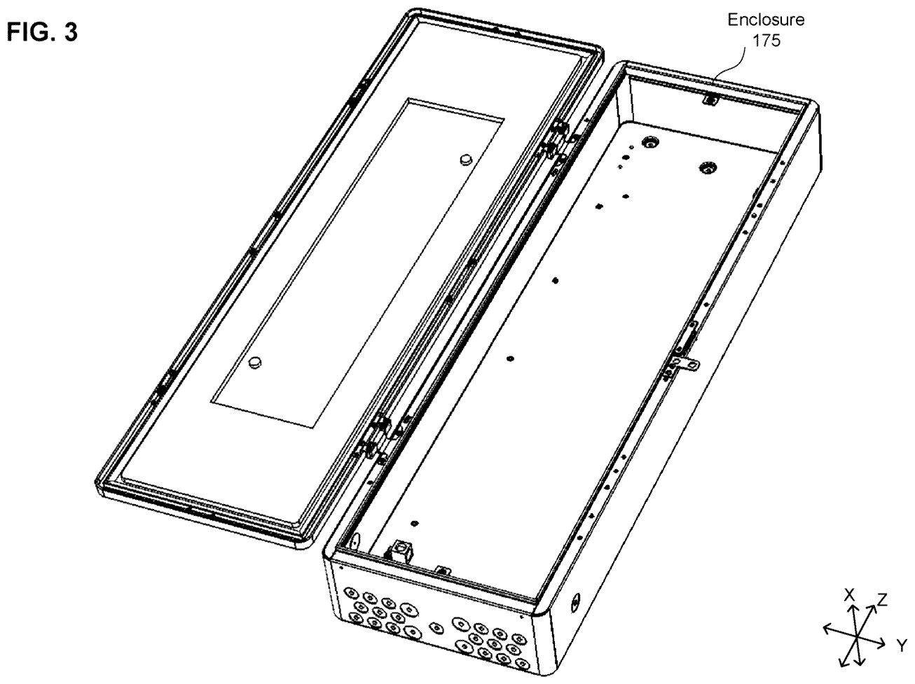

FIG. 2 is a perspective diagram of the electrical panel 100 with a different arrangement of electrical modules (and without deadfront 180). Specifically, in the example of FIG. 2, the panel 100 includes (from top to bottom) a mains module 500, branch modules 600A-B, an empty module receiving compartment 205, a branch module 600C, a PCM 700, and a gateway module 800. FIG. 3 is a perspective diagram of the enclosure 175 isolated from the spine and electrical modules.

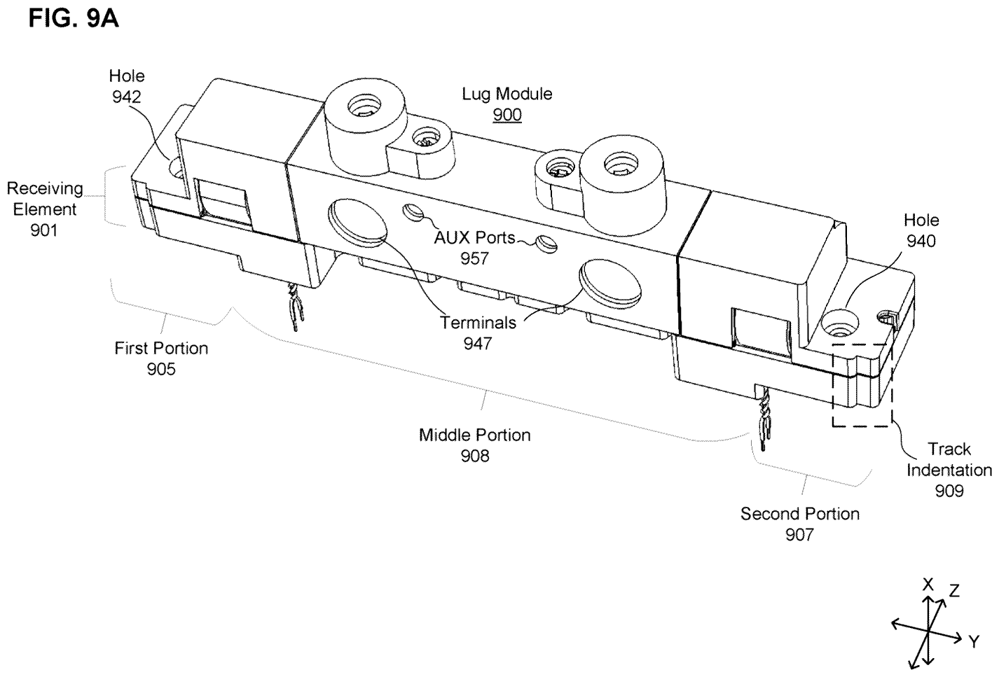

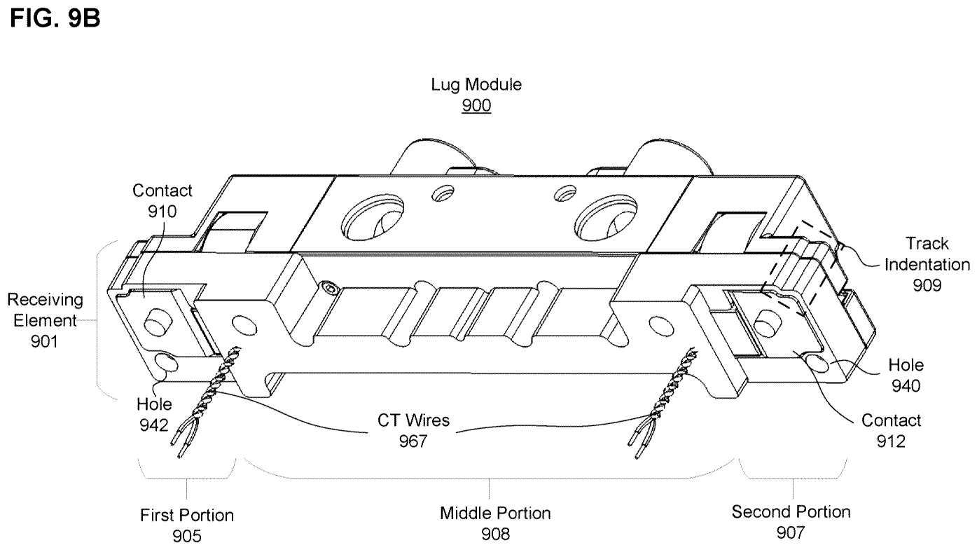

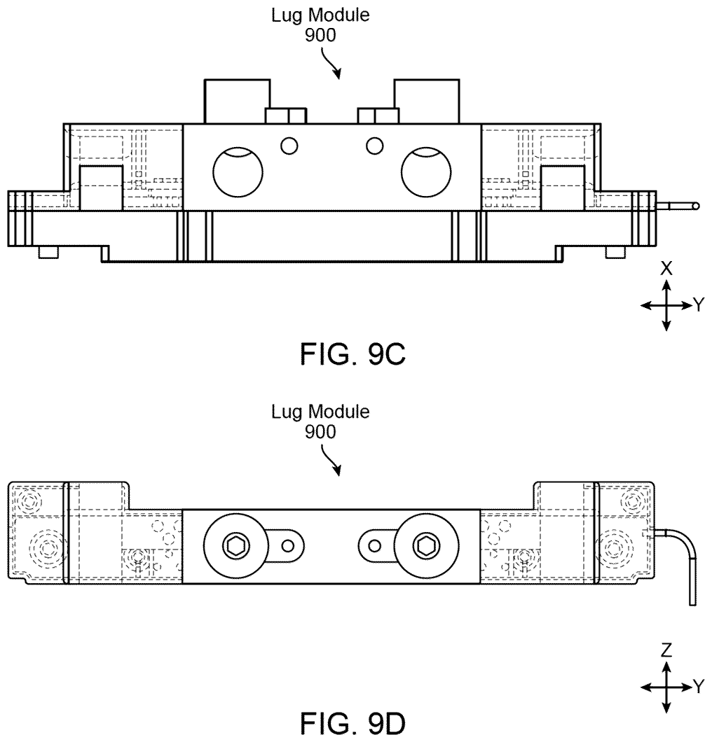

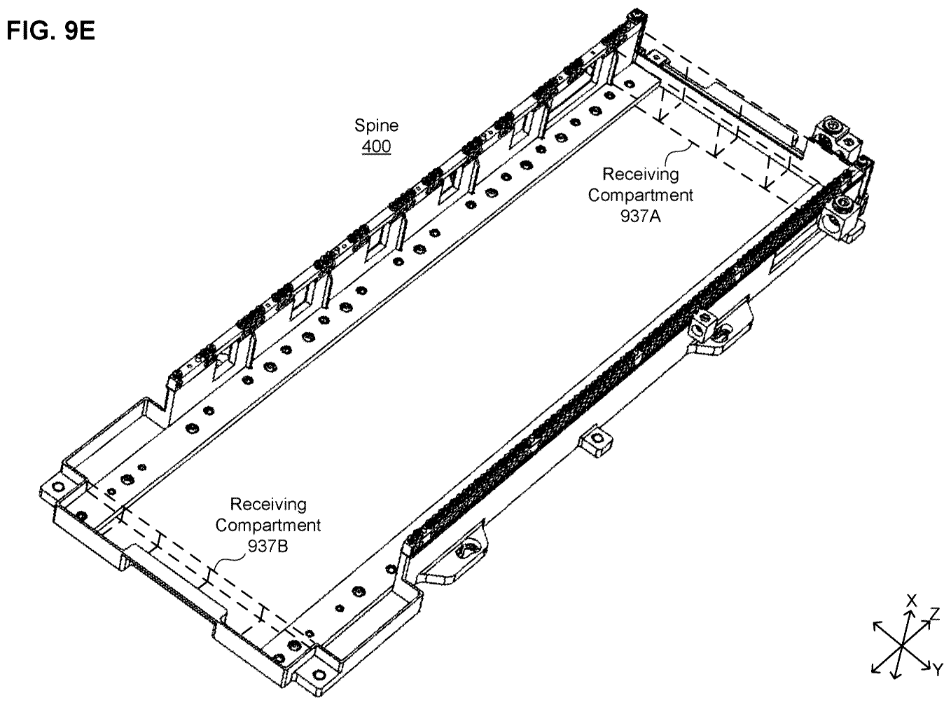

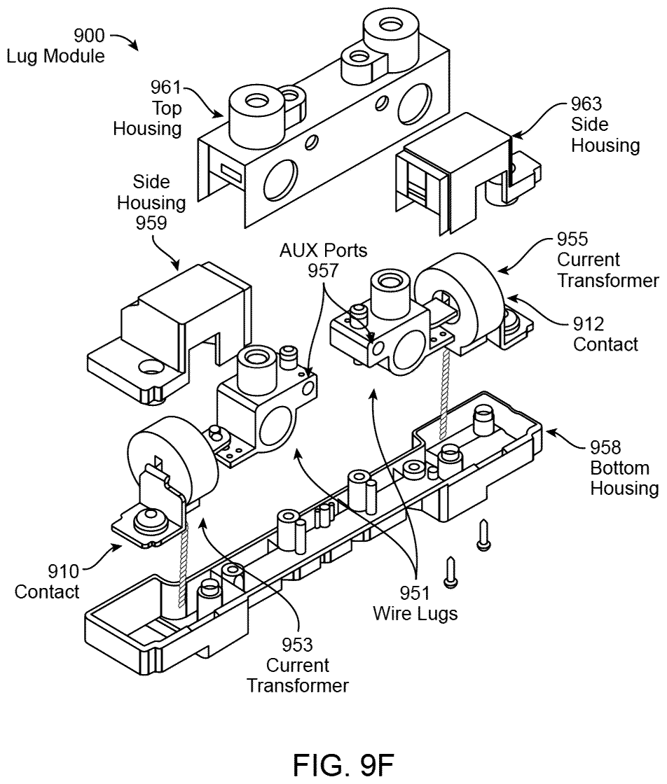

Although the descriptions herein are generally in the context of electrical panel 100, the descriptions herein are generally applicable to chassis that can receive modules and, more specifically, applicable to other types of electrical panels (e.g., the size of the panel and the number of modules may be different) which accommodate different electrical needs for different buildings. In a first example, a smaller panel includes three receiving compartments: a top receiving compartment with a mains module 500, a middle receiving compartment with a branch module 600, and a bottom receiving compartment with a PCM module 700. In a second example, a panel includes a top receiving compartment with a lug module (described with respect to FIG. 9), three middle receiving compartments with branch modules 600, and a bottom receiving compartment with a PCM module 700.

The spine 400 and the various electrical modules are further described below.

### Example Spines

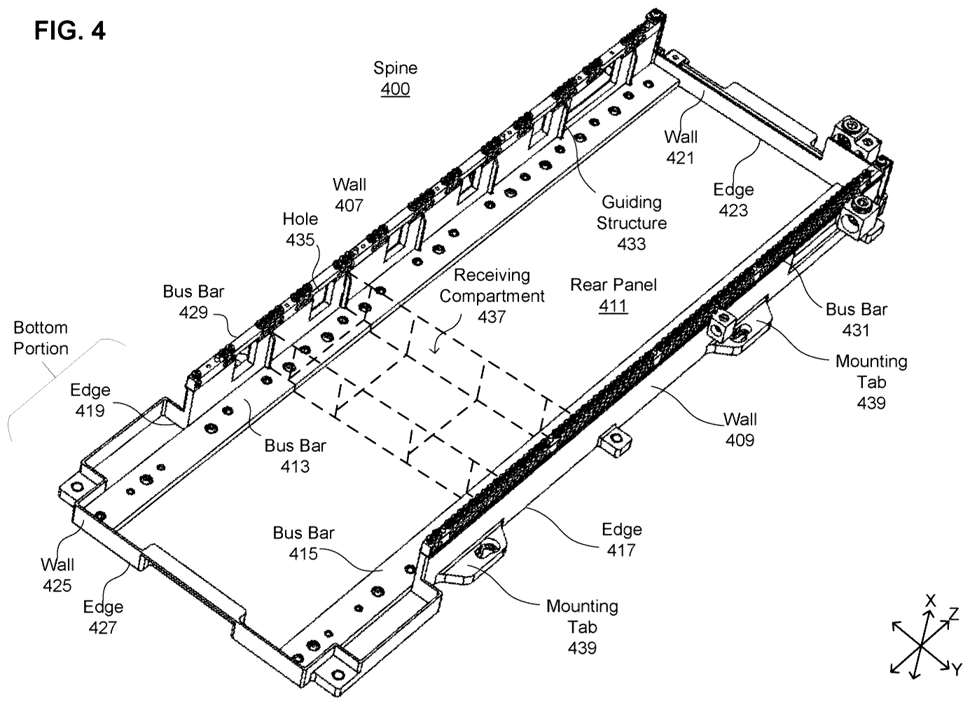

FIG. 4 is a perspective diagram of the spine 400 of the electrical panel 100. The spine 400 may be installed into the enclosure 175 via mounting tabs 439. The mounting tabs 439 include keyhole features that can receive a fastener. The mounting tabs 439 allow the spine 400 to easily be placed into and removed from the enclosure 175. Among other advantages, the spine 400 can be installed upside down (e.g., rotated 180 degrees about the x-axis in FIG. 4). This enables the spine 400 to be installed so that the feeder terminals (not labeled in FIG. 4) face the feeder wires regardless of whether the feeder wires are at the top or bottom (along the z-axis) of the enclosure.

In some embodiments, the spine 400 with modules installed in receiving compartments weighs a total of fifty pounds or less so that a single person (instead of two or more people) can install the spine 400 and the modules into the enclosure 175, thus reducing installation costs.

Among other advantages, the spine 400 includes receiving compartments (e.g., 437) that can receive different modular electrical components. Receiving compartments may also be referred to herein as “slots,” or “module slots,”). The receiving compartments (e.g., 437) enable different types of electrical modules to be installed on the electrical panel 100 (e.g., a branch module or a mains module) to accommodate the needs of the building. Said differently, an electrical module in a receiving compartment (e.g., a mains module) may be removed and replaced by an electrical module of a different type (e.g., a branch module). The receiving compartments are formed from the walls of the spin; bus bars 413, 415; and guiding structures (e.g., 433) as further described below. Note that the spine 400 can include additional of fewer receiving compartments than as illustrated in FIG. 4.

The spine 400 includes a rear panel 411 and walls 407, 421, 409, 425 that are raised (in the +x direction) from edges 419, 423, 417, 427 of the rear panel 411 and that extend along their respective edges. For example, wall 407 is raised from edge 419 and extends along edge 419. Similarly, wall 409 is raised from edge 417 (forming an opposite side of the spine 400).

Although many receiving compartments of spine 400 are the same size (or substantially the same size (i.e., the dimensions are within 10%), a spine may include different sized receiving compartments to accommodate different sized modules. For example, along the z-axis a spine can include any combination of 1.5 inch, 2 inch, 4 inch, and 8 inch receiving compartments. Furthermore, in the example of FIG. 4, the width of the spine 400 (along the y-axis) increases at a bottom portion. This creates a wider receiving compartment (relative to the other receiving compartments), thus enabling the spine 400 to receive a wider electrical panel component (e.g., the PCM module 700), which may otherwise not fit into other receiving compartments (e.g., 437). Among other advantages, this wider receiving compartment further increases the customizability of the electrical panel 100.

The spine 400 includes two rectangular bus bars 413, 415 in the cavity formed from the walls (in other words, the bus bars 413, 415 are between the walls of the spine 400). The bus bars 413, 415 are the L1 and L2 bus bars. The bus bars 413, 415 are coupled (e.g., secured or fixed) to the rear panel 411 (e.g., via heat staking, snap-features, or fasteners). The bus bars 413, 415 are in corners formed by the rear panel 411 and the walls 407, 421, 409, 425 (however this isn't required). Along the y-axis, the bus bars 413, 415 are spaced apart from each other and on opposite sides of the spine 400. Along the z-axis, the bus bars 413, 415 extend along the length of the spine 400. More specifically, each bus bar extends from wall 421 to wall 427 (however the bus bars are not required to extend the entire length of the spine 400). Thus, in the example of FIG. 4, the bus bars 413, 415 are on opposite sides of receiving compartment 437 (along the y-axis). The presence of both bus bars 413, 415 in a receiving compartment enables an electrical panel component (in the receiving compartment) to electrically couple to both bus bars 413, 415. Notably, the bus bars in the example of FIG. 4 do not include stabs.

The spine 400 includes rectangular bus bars 429, 431 coupled to top surfaces of walls 407 and 409 (e.g., via heat staking, snap-features, or fasteners). One of the bus bars (e.g., 429) may be a neutral bus bar and the other (e.g., 431) may be a ground bus bar.

The spine 400 includes multiple guiding structures (e.g., 433). Guiding structures may also be referred to herein as “mounting structures,” or “module guides.” The guiding structures engage with modular electrical components when they are placed into receiving compartments of the spine and prevent modular electrical panel components in the receiving compartments from sliding into adjacent receiving compartments (e.g., prior to the modules being fixed to the bus bars). More specifically, the guiding structures engage with track indentations (also “guide slots”) (e.g., on outer surfaces) of the of the modular electrical panel components as further described below.

The guiding structures may be fins or tabs that extend from inner surfaces of walls 407 and 409. To give a specific example, the guiding structure 433 is raised from an inner surface of wall 407 and extends toward the inner surface of wall 409, which is opposite wall 407 (in this context, “inner” is relative to the cavity of the spine 400). Each receiving compartment includes a set of one or more (e.g., four) guiding structures (e.g., in corners of the receiving compartments). In the example of FIG. 4, the guiding structures on wall 407 are aligned (along the z-axis) with guiding structures on wall 409 (not illustrated in FIG. 4).

Installing an electrical module may include placing (e.g., sliding) the module in a receiving compartment and securing the module into the receiving compartment (e.g., so the component remains fixed to and electrically coupled to both bus bars). A module may be secured to the spine 400 via fasteners (e.g., bolts, screws, push nuts, other snap fits, or any combination thereof), which may improve heat rejection. Thus, in the example of FIG. 4, the bus bars 413, 415 include a set of holes (to receive fasteners (e.g., bolts or screws)) for each of the receiving compartments so the modules can be directly secured to the bus bars 413, 415. Although the bus bars 413, 415 have holes in the example of FIG. 4, in other embodiments, one or more holes are located elsewhere, such as in the rear panel 411 between the bus bars 413, 415. The holes may have a standard and repeating hole pattern corresponding to the receiving compartment positions so that different modules can be secured to the bus bars regardless of which receiving compartment they are placed into.

However, an electrical module may be secured to bus bars of the spine 400 via other mechanisms (e.g., via spring loaded clips). For example, an electric module and the spine 400 include clip mechanisms configured to engage with each other when the module is placed in a receiving compartment. In a more specific example, an electric module includes a clip mechanism on one or both sides that engages with the side of the spine 400 (e.g., wall 407 and/or 409). Additionally, or alternatively, one or both sides of a module include a protrusion configured to engage with a clip mechanism on the spine 400 (e.g., at a wall). In another example, an electrical module may be secured to bus bars of the spine 400 via magnetic connections (e.g., via magnets secured (e.g., embedded) in the module and the spine. In some embodiments, an electrical module is electrically connected to a bus bar of the spine 400 via one or more pogo pins.

In some embodiments, the modules in the receiving compartments may be independently powered and communicate with one another. In order to achieve this, a wired connection may be installed between modules to provide DC voltage and signals (e.g., over a CAN bus interface or the like) (the connection may carry 3.3V or 5V). Thus, one or more of the side walls (407 and 409) may include one or more holes (or “cavities”) (e.g., 435) aligned with the receiving compartments (e.g., 435) for wires of these connections (e.g., each receiving compartment may include at least one corresponding hole in a side wall). Among other advantages, these side wall holes (e.g., 435) ease installation of the wired connections.

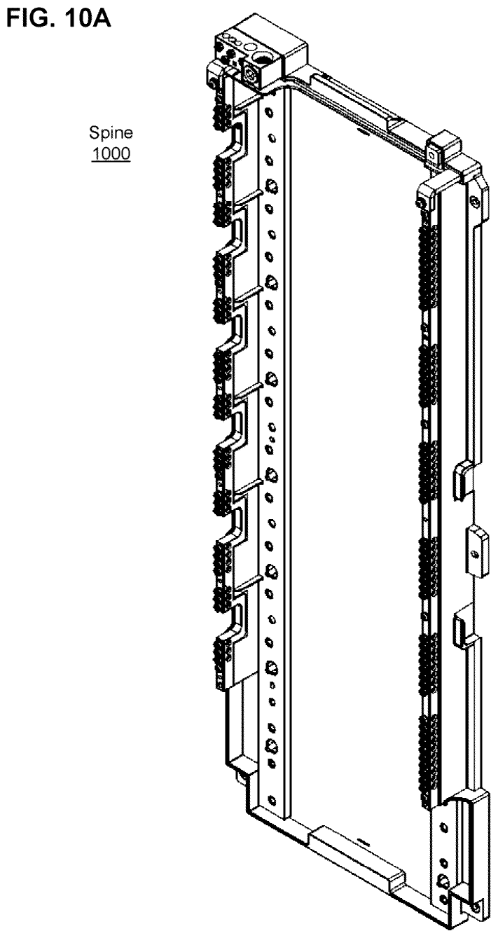

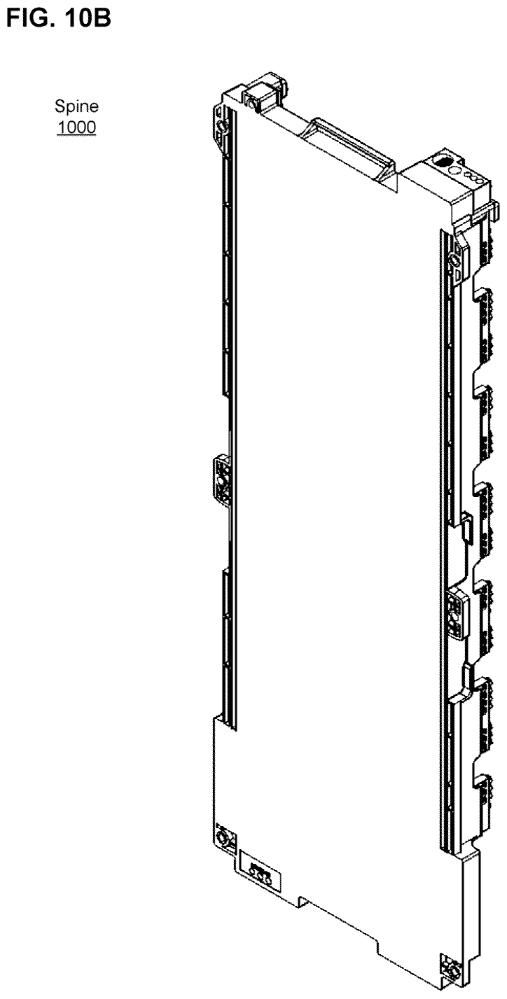

FIGS. 10A-10B are diagrams of a second example spine 1000 of the electrical panel 100. Labels for components of spine 1000 are omitted in FIGS. 10A-10B for simplicity.

Although the above descriptions with respect to FIGS. 4 and 10A-10B describe many features, a spine is not required to include all of these features. For example, some spine embodiments may not include: all four walls 407, 409, 421, 425; guiding structures 433, mounting tabs 439, holes one or both of the bus bars 413, 415 (for mounting the modules); or any combination thereof.

### Example Mains Modules

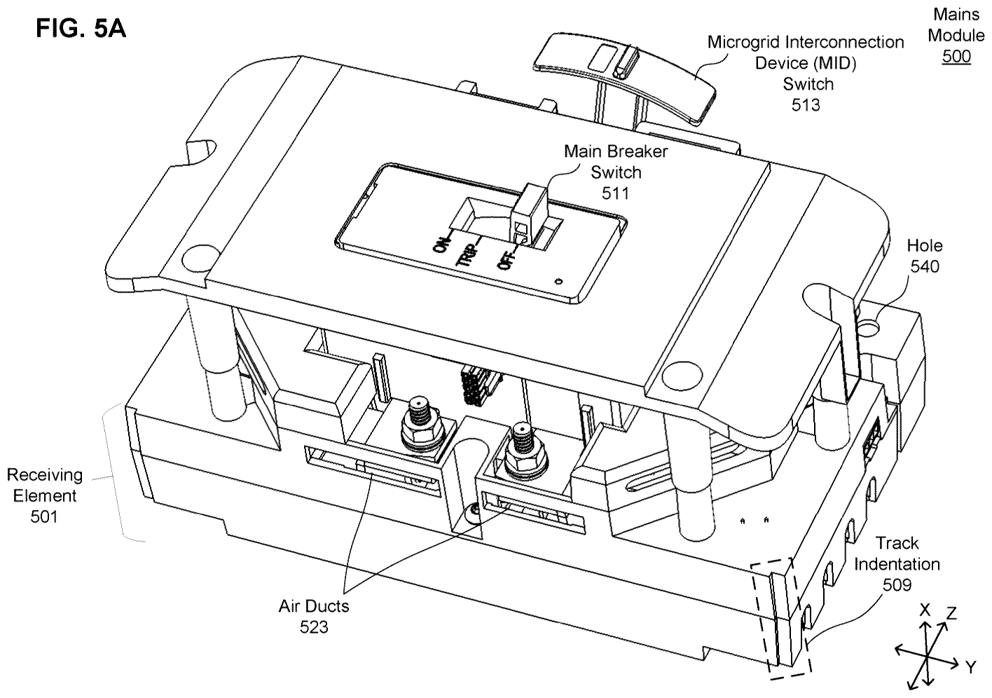

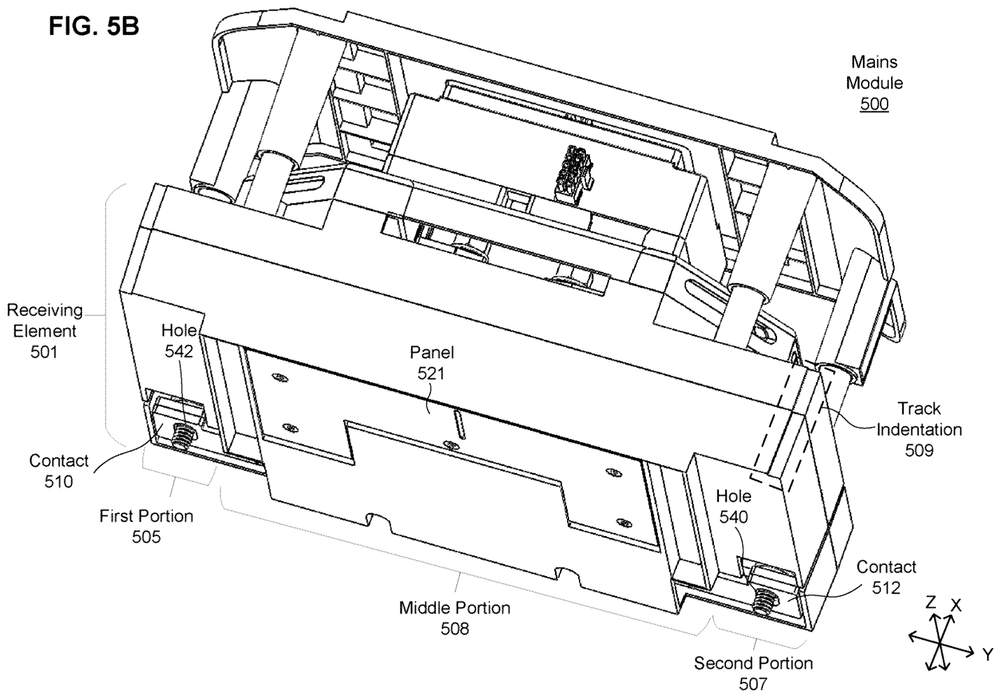

In some embodiments, the electrical panel 100 includes a mains module 500. The mains module 500 is a modular electrical panel component that may be installed into one (e.g., of many) of the receiving compartments of the spine 400 (however, practically the mains module 500 may be installed into one of the top receiving compartments of the spine to couple to the feeder wires). FIGS. 5A-B (“FIG. 5” collectively) are diagrams of an example mains module 500. Specifically, FIG. 5A is a perspective diagram of an example mains module 500 illustrating the front side of the module 500. FIG. 5B is a perspective diagram of the mains module 500 illustrating the back side of the module 500 (that engages with the spine 400).

The mains module 500 may include the main breaker of the panel 100, a MID (Microgrid Interconnection Device), or some combination thereof (e.g., no main breaker and no MID). In the example of FIG. 5, the mains module includes a main breaker and a MID (e.g., see switches 511 and 513 in FIG. 5A). The mains module 500 may provide a location to connect the main feeders to the panel 100 (and thus provide power to the bus bars 413, 415), provide overcurrent protection, and/or a disconnect. The mains module 500 may be rated up to 200 amps. If the mains module 500 includes an MID, the MID allows the panel 100 to isolate itself from the grid.

The mains module 500 includes a receiving element 501 (also referred to as an “insertion element”). The receiving element 501 is a container or cartridge shaped to slide into a module receiving compartment of the spine 400 (e.g., one of many receiving compartments) and be fixed to the bus bars in the receiving compartment. The receiving element 501 includes a first portion 505 on a first side of the receiving element 501, a second portion 507 on a second side of the receiving element 501 (e.g., an opposite side (along the y-axis)), and a middle portion 508 between the first and second portions. The first portion 505 receives and directly couples to a first bus bar (e.g., 415). Similarly, the second portion 507 receives and directly couples to a second bus bar (e.g., 413). Since the bus bars 413, 415 may pass through the receiving compartments, the first and second portions may extend along the length of the mains module 500 (along the z-axis) to accommodate each bus bar.

The first portion 505 includes a metal electrical contact (also “bus bar contact”) 510 and the second portion 507 includes an electrical contact 512. Both contacts 510, 512 physically contact a bus bar of the spine 400 (when the module 500 is in a receiving compartment).

As previously described, a module (e.g., the mains module 500) may be secured to (bus bars of) the spine 400 via fasteners (e.g., bolts or screws). Thus, the receiving element 501 (e.g., the first and second portions) may include a set of holes to receive fasteners (e.g., bolts or screws). For example, see holes 540, 542 in FIGS. 5A and 5B. The holes may have a (e.g., standard) pattern or arrangement on the receiving element 501 that matches the hole pattern of the bus bars.

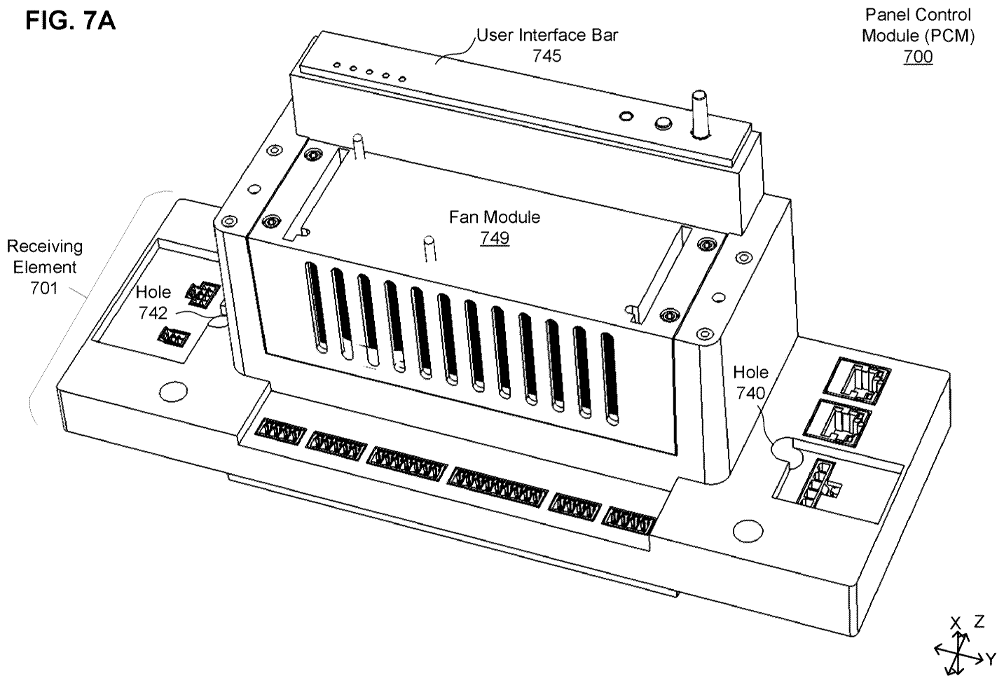

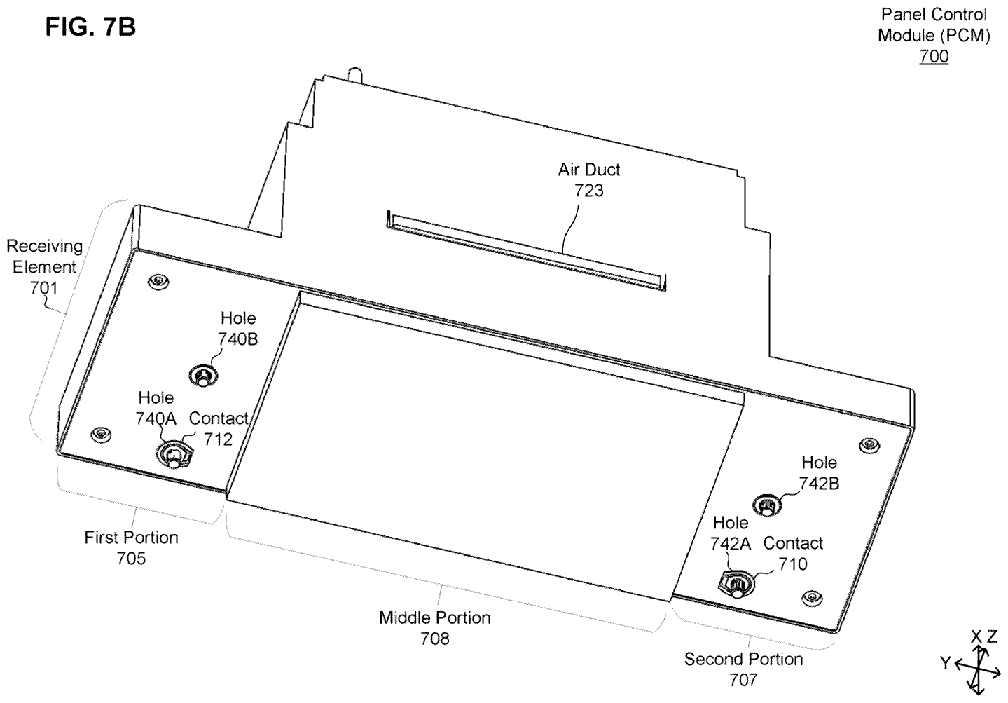

The receiving element 501 includes a middle portion 508 between the first and second portions 505, 507. In the example of FIGS. 5A and 5B, the middle portion 508 extends along the −x direction farther than the first and second portions 505, 507. Thus, the middle portion 508 engages with a gap between the bus bars 413, 415 when the receiving element 501 is in a receiving compartment. In the example of FIG. 5B, the middle portion 508 includes an (e.g., aluminum) panel 521 to increase heat dissipation during operation of the panel 100. The middle portion 508 also includes air ducts 523. The air ducts 523 allow air to pass through internal components of the mains module 500 to further improve heat management. Other modules may include similar air ducts so that, when installed on a panel, the air ducts of each module align with each other to create a long airflow passage along the panel 100, thus helping with thermal management of the panel 100. A fan module 749 in the PCM 700 may create an air current through the module air ducts (the fan module is further described with respect to FIG. 7C). In some embodiments, an electrical module with an air duct includes one or more fins inside the module to direct air flow inside the module (e.g., to specific internal components of the module). Fan fins to direct air from the fan into the modules may be referred to as plenum.

The receiving element 501 also includes track indentations (e.g., 509) that extends along the sliding direction of the receiving compartment (which is along the x-axis in the figures). As illustrated, the track indentation 509 is on an external surface of the receiving element 501 (however, this is not required). The track indentation 509 is configured to engage with a guiding structure (e.g., 433) of the spine 400 to (a) guide placement of the mains module 500 into the modular spot and retain the mains module 500 in the receiving compartment after placement. Thus, the receiving element 501 may include one or more track indentations (e.g., four) aligned with an arrangement of one or more guiding structures in a receiving compartment. In the example of the mains module 500, the receiving element 501 includes track indentations at corners of the receiving element 501.

Although not illustrated in FIG. 5, the receiving element 501 may include a port for a wired connection. The port is on a side parallel to the xz plane. When the receiving element 501 is in a receiving compartment of the spine 400, the port is on a side of the receiving element 501 facing wall 407 and aligned with a hole (e.g., 435), which allows an installer to connect the wire to the port to establish the connection. As previously described, the wired connection may provide DC voltage and signals (e.g., over a CAN bus interface or the like) to and/or from the module 500.

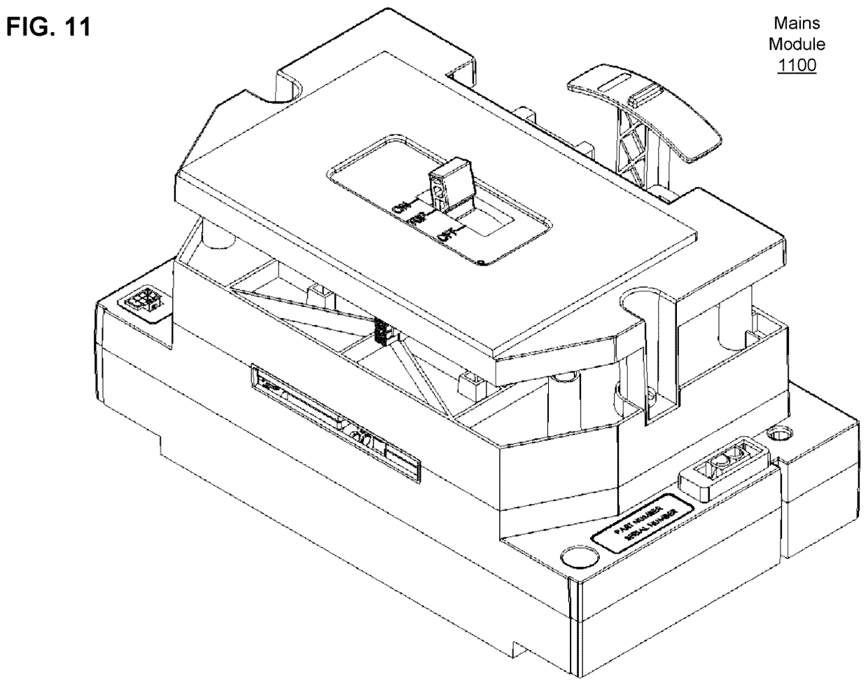

FIG. 11 is a diagram of a second example mains module 1100 of the electrical panel 100. Labels for components of mains module 1100 are omitted in FIG. 11 for simplicity.

### Example Branch Modules

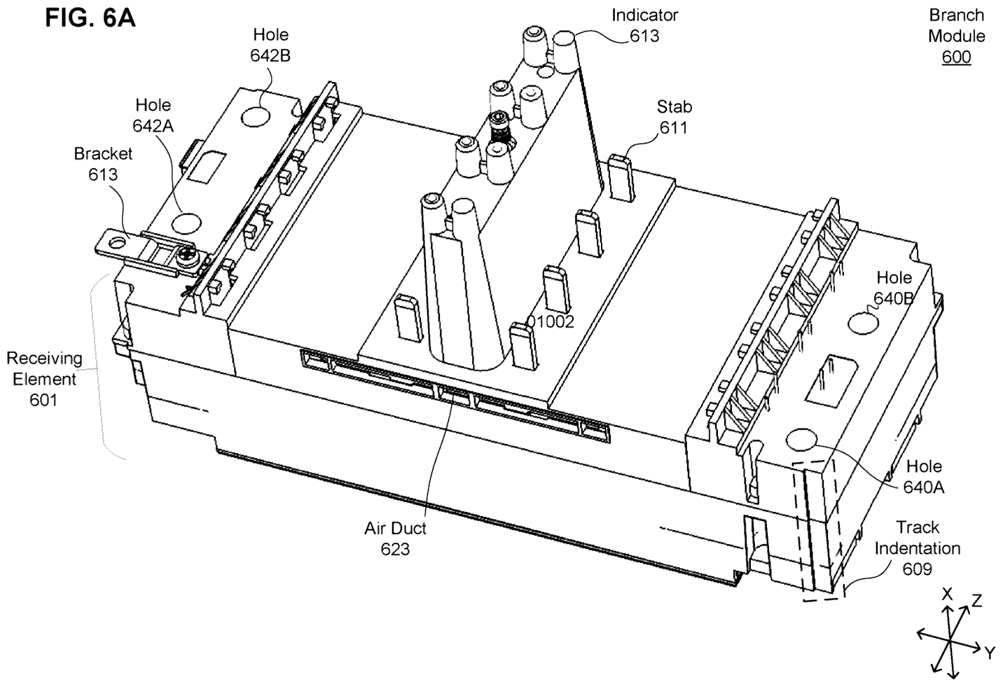

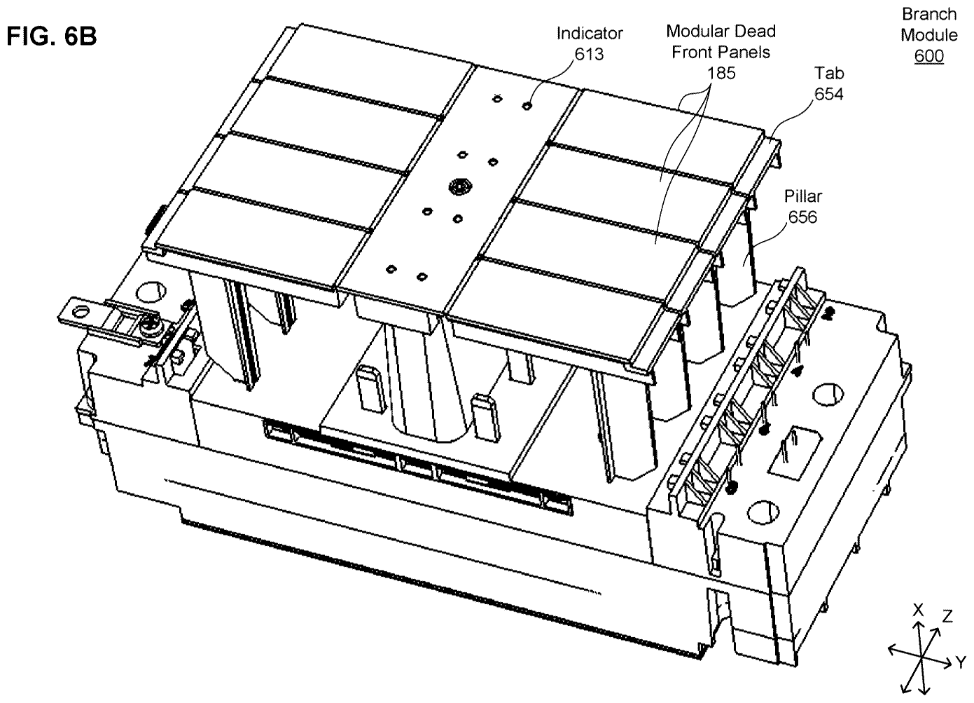

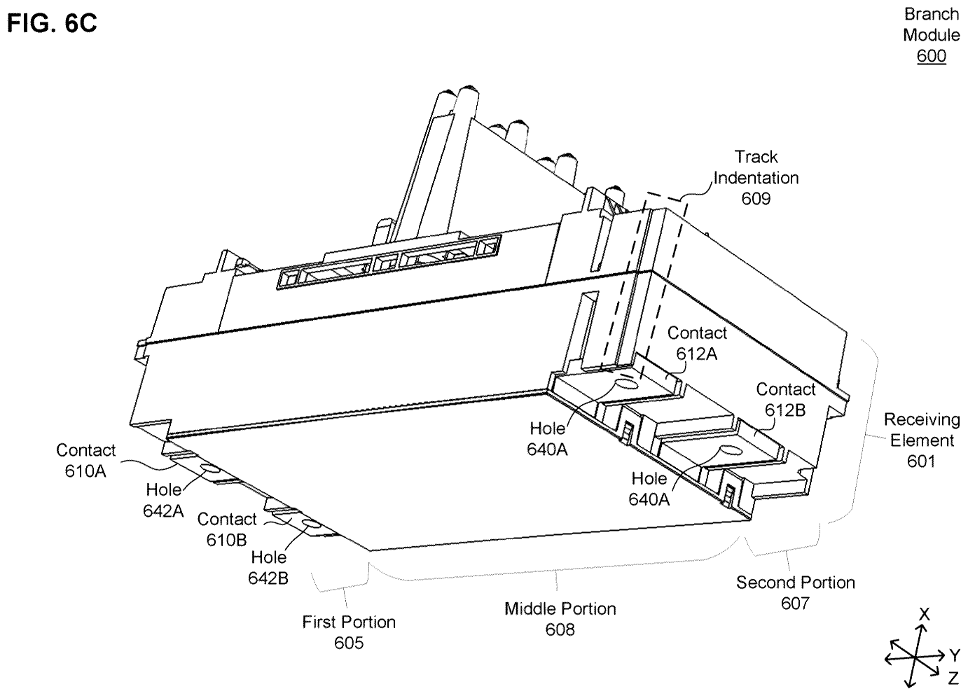

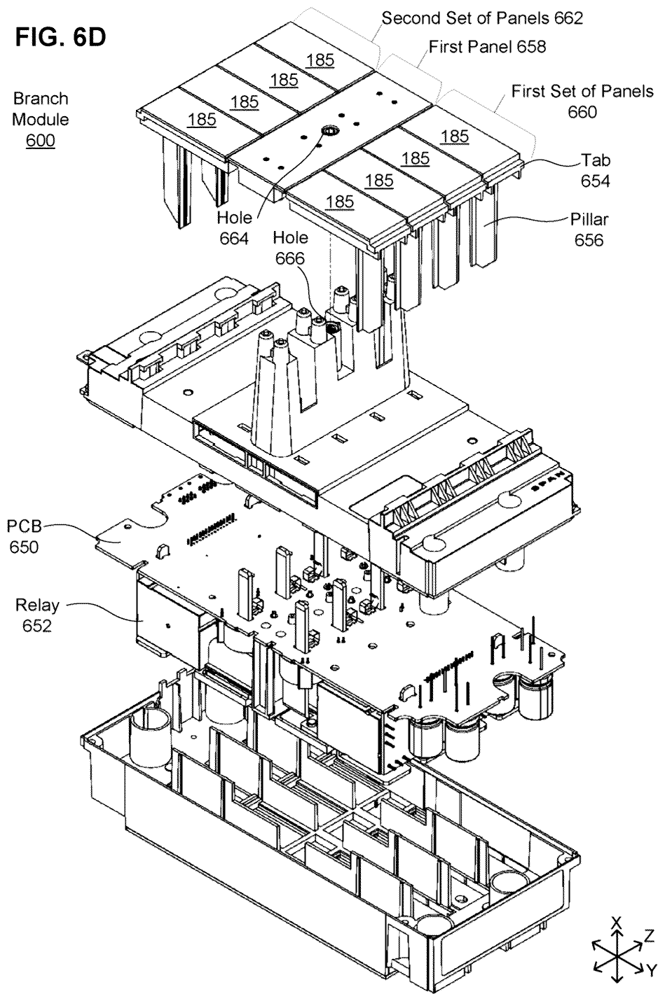

In some embodiments, the electrical panel 100 includes a branch module (e.g., 600). The branch module (e.g., 600) is a modular electrical panel component that may be installed into one (e.g., of many) of the receiving compartments of the spine 400. Since a building (e.g., a residential building) may include many circuits, a panel may include multiple branch modules 600 to accommodate the expected electrical needs of the building. FIGS. 6A-D (“FIG. 6” collectively) are diagrams of an example branch module 600. Specifically, FIG. 6A is a perspective diagram of the branch module 600 illustrating the front side of the module. FIG. 6B is similar to FIG. 6A, except the branch module 600 additionally includes modular dead front panels 185. FIG. 6C is a perspective diagram of the branch module 600 illustrating the back side of the module (that engages with the spine 400).

A branch module (e.g., 600) is configured to manage a set of electrical branch circuits within the overall electric system for a building, where a branch circuit corresponds to an electrical circuit in the building. For example, a branch module distributes electricity from the bus bars (e.g., 413, 415) to the branch circuits.

Similar to the receiving element 501 of the mains module 500, the receiving element 601 of the branch module 600 includes a first portion 605, a middle portion 608, a second portion 607, track indentations (e.g., 609), a port for a wired connection (not illustrated) and an air duct 623 with similar mechanical configurations and functionalities. Due to this, descriptions of these components are omitted for brevity. The receiving element 609 also includes electrical contacts 610, 612 and holes 642, 640 at the first and second portions 605, 607 (similar to the receiving element 501), however, unlike the receiving element 501, the receiving element 609 includes two electrical contacts 610A, 610B and two holes 642A, 642B at the first portion 605 and includes two electrical contacts 612A, 612B and two holes 640A, 640B at the second portion 607 (for a total of four electrical contacts that contact bus bars of the spine 400 and a total of four holes to receive fasteners that secure the contacts to the bus bars). Similar to the receiving element 501, the holes of the receiving element 601 may have a (e.g., standard) pattern that matches the hole pattern of the bus bars.

The example branch module 600 includes eight switched circuit branches (however additional or fewer circuits are possible for a branch module). Each circuit branch includes a stab (e.g., stab 611) which can engage with an overcurrent circuit breaker installed on the branch module 600. In some embodiments, the branch module 600 is rated up to 200 amps. The branch module 600 may include additional branch circuit functionalities, such as current or voltage sensing, AFCI protection, light (e.g., LED) indication, or some combination thereof for each circuit branch.

The modular dead front panels 185 provide touch-safe interfaces to homeowners. Additionally, the panels 185 can be individually removed (e.g., snapped off) from each other and from the branch module 600 to accommodate additional overcurrent circuit breakers as the breakers are installed on the module 600.

The branch module 600 includes a bracket 613 protruding from a top surface to contact a neutral bus bar (e.g., 429) of the spine (e.g., to enable current or voltage metering). The bracket 613 may be bolted to the neutral bus bar.

The branch module 600 includes an indicator (e.g., indicator 613) for each of the switched circuit branches. Each indicator includes a light source (e.g., an LED) in the branch module 600 and a light pipe that directs light from the source to the external environment. Each indicator may illuminate light indicating the state of a relay (e.g., an electrically operated switch) in the associated circuit branch (e.g., a green light indicates the relay is closed). As illustrated in FIG. 6B, the indicators can be seen through the dead front. Thus, the indicators may allow a user to easily and quickly determine the states of each relay of each branch module. Note that indicators are also illustrated in FIGS. 1A-2.

FIG. 6D is an exploded view diagram of the branch module 600. FIG. 6D illustrates components contained within the branch module 600, such as a PCB 650 (printed circuit board) and relays (e.g., 652). Branch module 600 includes a separately controllable relay for each branch circuit. Branch module 600 also includes current sensors for each branch module (not labeled in FIG. 6D). PCB 650 can receive current sensor signals from the current sensors and control the relays based on the received signals. The single PCB provides the technical advantage of reducing processor redundancy (compared to a separate PCB for each branch circuit) and allows for more advanced functionalities. In the example of FIG. 6D: (a) the plane of the PCB 650 is substantially parallel to rear panel 411 (e.g., within 5 degrees), (b) the relays are below the PCB (along the x-axis), and (c) stabs protrude through holes of the PCB 650. However other branch modules are not required to include all of these components and features (other branch modules may include any combination of these components and/or features).

As illustrated in FIG. 6D, a dead front for a branch module (e.g., 600) of an electrical panel (e.g., 100) may include: a first panel 658, a first set 660 of modular panels (individual panels are labeled 185), a second set 662 of modular panels (individual panels are also labeled 185), or any combination thereof. The first panel 658 may extend along the z-axis (e.g., along the entire z-length of the branch module). A modular panel 185 may be aligned with a slot configured to receive an overcurrent electrical panel (e.g., its aligned with a stab). Thus, modular panels 185 can be individually removed to add attached more overcurrent circuit breakers to the branch module (e.g., to increase the number of branch circuits managed by 600),

A modular panel 185 may include a tab (e.g., 654) to help secure the panel 185. The tab may engage with dead front panel 180 of panel 100 (e.g., the tab is positioned behind dead front panel 180). This may help prevent a user (e.g., a homeowner) from pulling a panel 185 outward (along the +x direction). A modular panel 185 may additionally, or alternatively, include a support structure (e.g., 656), such as a pillar, column, or post to help secure the panel 185. The support structure extends downward (−x direction) from the bottom surface of the panel 185 and may contact a top surface of the branch module (the surface where an overcurrent circuit breaker would otherwise be placed). The support structure may help prevent a homeowner from removing a panel 185 by pressing inward into the panel (along the −x direction).

A dead front for a branch module may be coupled to a branch module via hole 664 and a fastener (e.g., a screw) that engages with a corresponding hole 666 of the branch module. The underside of the first panel 658 may also be shaped to engaged with the top elevated structures of the branch module (e.g., end portions of the light indicators (e.g., 613). Note that first panel 658 also includes smaller holes (not labeled) that allow light from the indicators (e.g., 613) to propagate into the external environment.

Example PCMs (Panel Control Modules)

In some embodiments, the electrical panel 100 includes a PCM (panel control module) 700. The PCM 700 is a modular electrical component that may be installed in a receiving compartment of the spine 400. Since the example PCM 700 is wider than other modules, the PCM 700 may be installed on the wide receiving compartment of spine 400 (at the bottom portion). FIGS. 7A-B (“FIG. 7” collectively) are diagrams of an example PCM (panel control module) 700. FIG. 7A is a perspective diagram of the PCM 700 illustrating the front side of the module 700. FIG. 7B is a perspective diagram of the PCM 700 illustrating the back side of the module 700 (that engages with the spine 400).

In general, the PCM 700 manages control of the electrical panel 100. For example, the PCM 700 performs computations (e.g., for powerup functionalities) and provides power to the other modules on the panel 100. The PCM 700 includes a user interface (UI) bar 745 which may give users (e.g., a homeowner) the ability to read the state of the panel 100 and interact with and control the panel 100.

As previously discussed, the PCM 700 includes a fan module 749. FIG. 7C is a transparent perspective diagram of an example fan module 749 that fits into the PCM 700. The fan module 749 includes two fans that create airflow through air duct 723 to increase dissipation throughout the panel 100.

Similar to the receiving element 501 and the receiving element 601, the receiving element 701 of the PCM 700 includes a first portion 705, a middle portion 708, a second portion 707, an air duct 723, electrical contacts 710, 712, a port for a wired connection, and holes 742A-B, 740A-B with similar mechanical configurations and functionalities (note that in FIG. 7B, bolts are in holes 740A-B, 742A-B). Due to this, descriptions of these components are omitted for brevity. That being said, note that the PCM 700 does not include track indentations since the PCM 700 is shaped to slide into the wide receiving compartment of the spine 400.

### Example Gateway Modules

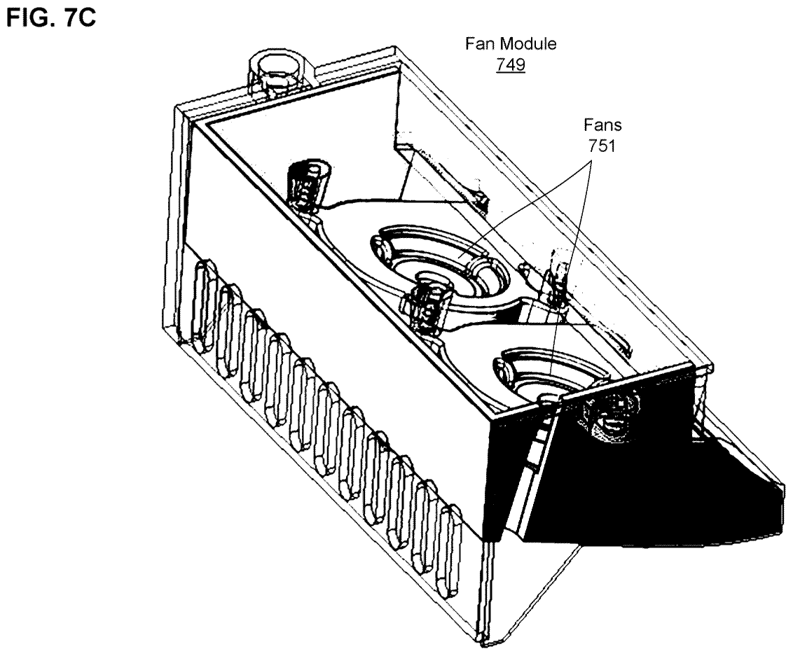

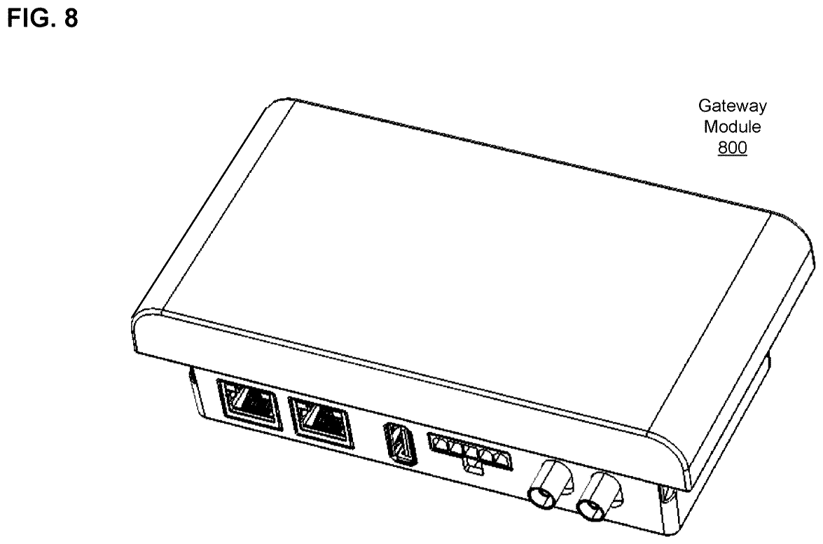

In some embodiments, the panel 100 includes a gateway module that couples to the PCM 700. FIG. 8 is a perspective diagram of an example gateway module 800. The gateway module 800 may be a site controller for a building (e.g., a residential home). If the building includes multiple panels, the gateway module 800 can receive and aggregate data from the multiple panels and determine building-wide control decisions and reports (thus, a building with multiple panels may only use a single gateway module). For example, the gateway module 800 determines decisions for powerup and can send panel reports to a cloud server (pending user permissions). The gateway module 800 may include computer components associated with the above functions, such as a set of processors, a computer readable medium, and antennas.

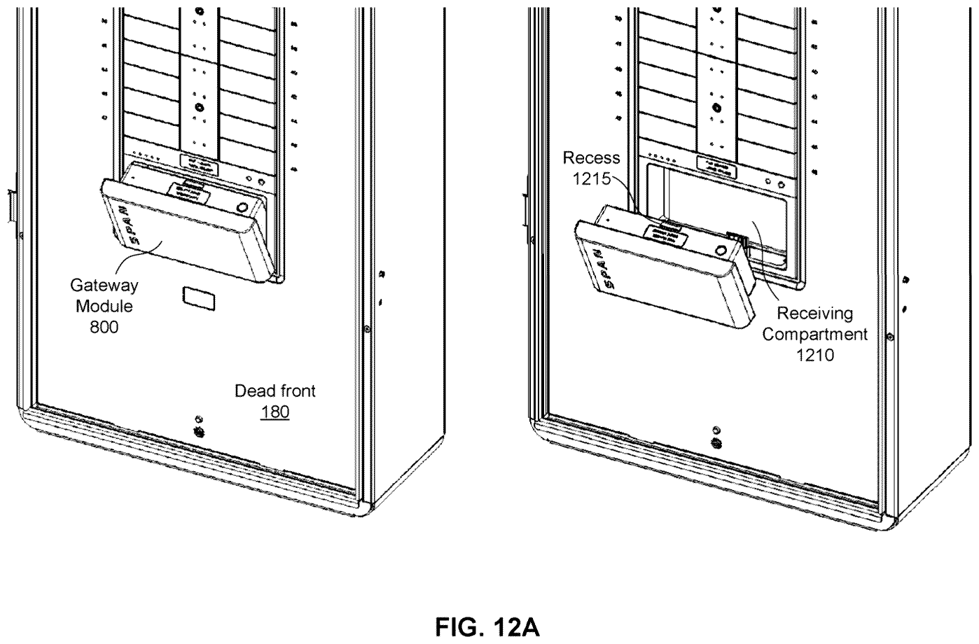

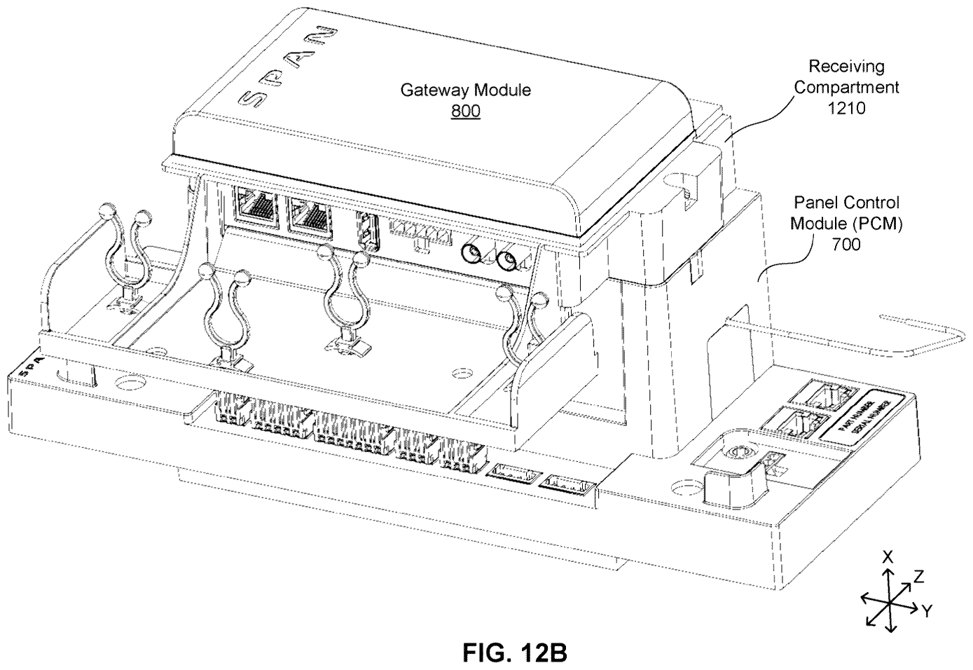

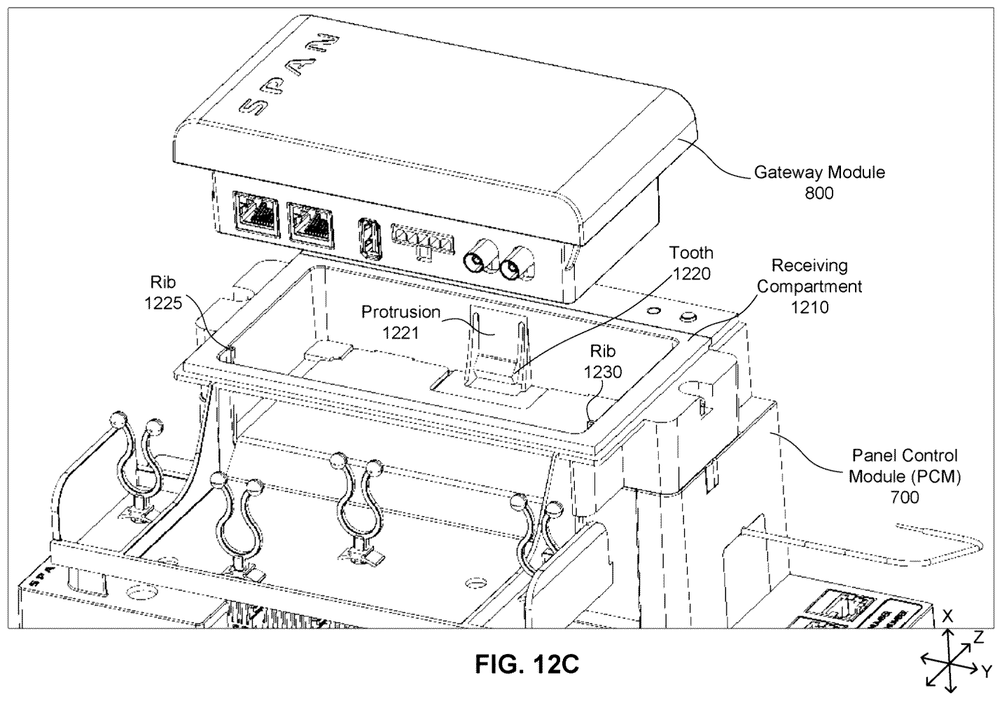

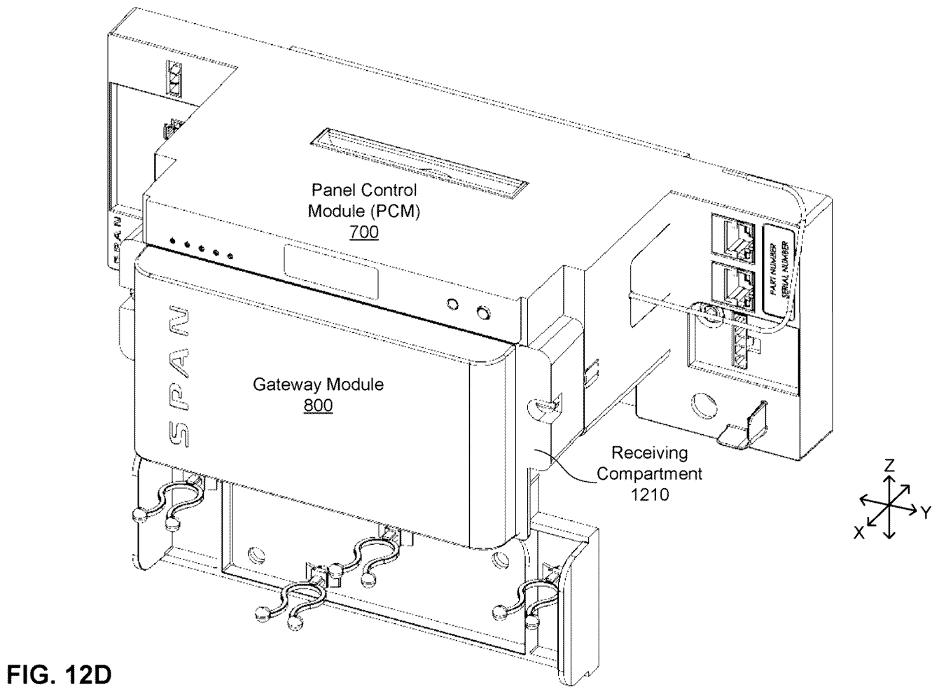

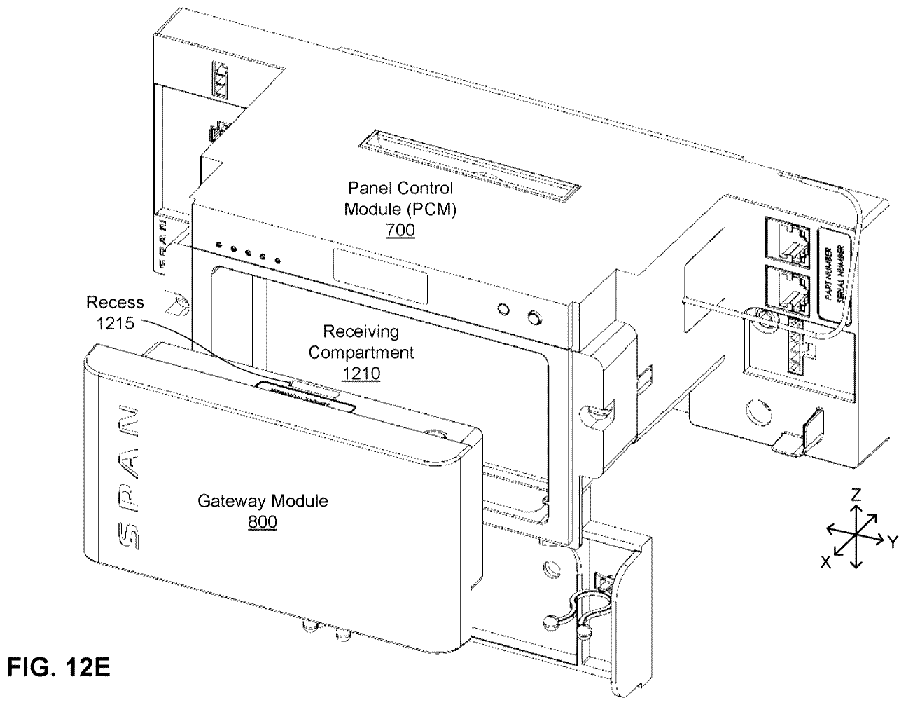

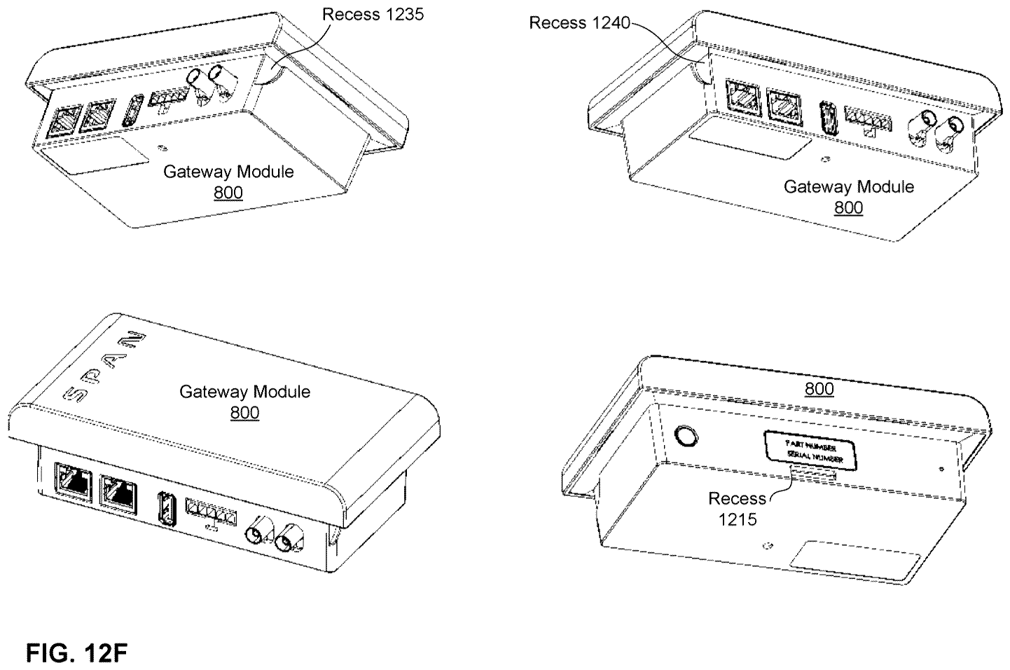

Gateway module 800 may plug, snap, or otherwise connect into a receiving compartment on PCM 700 (e.g., receiving compartment 1210 in FIGS. 12A-12E). For example, gateway module 800 is held in the receiving compartment by snap feature that mates and/or engages with a recess formed by the housing (also referred to as an enclosure) of the gateway module 800 (e.g., recess 1215 (also referred to as a notch)). The snap feature may include a protrusion (e.g., 1221) with a tooth (e.g., 1220) that engages/mates with the recess. The angle of the tooth edge may be configured such that the snap feature holds the gateway module 800 in place, but a user can remove gateway module 800 by applying a (e.g., suitable) pulling force to gateway module 800 away from the panel 100. For example, the angle of the tooth edge is an obtuse angle.

Features of the gateway housing and/or receiving compartment may control the path of gateway module 800 into and out of the receiving compartment. For example, the receiving compartment includes curved ribs on two sides of the gateway module 800 (e.g., rib 1230 and rib 1225) that engage and/or mate with recess on sides of gateway module 800 with curved edges (e.g., recess 1235 and recess 1240). For example, see FIGS. 12C and 12F. In this example, to remove gateway module 800 from compartment 1210, the surface of gateway module 800 with recess 1215 rotates away from compartment 1210. More specifically, gateway module 800 pivots about the bottom side (e.g., the side with cable ports, which is on an opposite side as recess 1215) due to the curvature of rib 1230 engaging with recess 1235 and the curvature of rib 1225 engaging with recess 1240. After pivoting, gateway module 800 can be removed from compartment 1210. FIG. 12A includes two diagrams illustrating removal of gateway module 800 (after the rotational pivot) from an electrical panel. Among other advantages, the features may allow a user to remove gateway module 800 and replace cables configured to connect to gateway module 800. For example, the receiving compartment is arranged such that the cables do not fall into the unit and the path of the gateway is such that it does not lead to a cable breaking off. In some embodiments, compartment 1210 includes the curved recesses and gateway module 800 includes curved ribs.

### Example Lug Modules

In some embodiments, the electrical panel 100 includes a lug module 900. The lug module 900 is a modular electrical panel component that may be installed into one (e.g., of several) of receiving compartments of the spine 400. FIGS. 9A-D and 9F are diagrams of an example lug module 900. Specifically, FIG. 9A is a perspective diagram of the lug module 900 illustrating the front side of the lug module 900. FIG. 9B is a perspective diagram of the lug module 900 illustrating the back side of the lug module 900 (that engages with the spine 400). FIG. 9C is a lateral side view of the lug module 900, and FIG. 9D is a front view of the lug module 900. FIG. 9F is an exploded view diagram of the lug module 900. FIG. 9E is a diagram illustrating example lug module receiving compartments 937A-B of the spine 400. Note that FIGS. 9A-F may collectively be referred to as FIG. 9.

The panel 100 may include a lug module 900 when the panel doesn't include a mains module 500. The lug module 900 provides power from the feeder wires to the bus bars 413, 415. To do this, the lug module 900 may be installed in a top receiving compartment 937A or a bottom receiving compartment 937B of the spine 400. Since the lug module 900 is typically smaller (along that z-axis) than other modules (e.g., a branch module 600), the receiving compartments 937A-B may be smaller (along the z-axis) to accommodate lug modules. The lug module 900 includes terminals 947 for the feeder wires and electrical contacts 910, 912 to power the bus bars 413, 415. In some embodiments, the lug module 900 advantageously includes integrated current sensors (e.g., current transformers 953, 955). The CT wires 967 can transmit current measurement data from current transformers 953, 955 to other components (e.g., to the PCM module)), which allows lug module 900 to provide additional functionalities, such as powerup functionality. The lug module 900 may be rated up to 200 amps.

Similar to receiving elements 501 and 601, the receiving element 901 of the lug module 900 includes a first portion 905, a middle portion 908, a second portion 907, track indentations (e.g., 909), electrical contacts 910, 912 (two in total), and holes 942, 940 (two in total) with similar mechanical configurations and functionalities. Due to this, descriptions of these components are omitted for brevity.

FIG. 9F illustrates individual components of lug module 900. Housing components include bottom housing 958, top housing 961, side housing 959, side housing 963, and bottom housing 958. Internal components of lug module 900 include wire lugs 951 (with auxiliary ports 957), current transformers 955, 953, and contacts 910, 912. The lugs 951 receive feeder wires (placed in terminals 947). The lugs 951 help secure the feeder wires to maintain an electrical connection to the electrical panel 100. In the example of FIG. 9F, the lugs have barrels where ends of the feeder wires are inserted and secured (e.g., via a screw). The auxiliary ports 957 of the lugs 951 include smaller barrels (arranged along the same direction as the main barrels) that can receive additional wires. These additional wires can be secured to the auxiliary ports 957 by tightening screws at sides of the lugs (not labeled in FIG. 9). Among other advantages, the auxiliary ports 957 allow a user (e.g., a technician) to electrically access the bus bars (e.g., without removing a module of the panel 100). For example, a technician can install surge protection equipment by inserting corresponding wires of the equipment into the auxiliary ports 957.

Although the above module descriptions with respect to FIGS. 5-7 and 9 describe many features, an electrical module is not required to include all of these features. For example, some electrical module embodiments may not include: a first portion (e.g., 505), a second portion (e.g., 507), a middle portion (e.g., 508), holes (e.g., 540, 542), track indentations (e.g., 509), contacts (e.g., 510, 512), or some combination thereof.

### Additional Spine Examples

Although FIG. 4 provides an example spine 400 and FIGS. 10A-10B provide a second example spine 1000, the below paragraphs describe additional example spines. The spines described below may omit features illustrated in FIGS. 4 and 10A-10B and/or include features that are in addition to or alternative to the features illustrated in FIGS. 4 and 10A-10B.

In some embodiments, a spine (e.g., 400, 1000) of a chassis (e.g., electrical panel 100) includes receiving compartments (e.g., 437) configured to receive chassis modules (e.g., 500, 600, 700, 900, 1100). Each receiving compartment is formed by (a) a portion of a panel (e.g., 411); (b) a portion of a wall (e.g., 407) raised from a first edge (e.g., 419) of the panel and extending along the first edge; (c) portions of two bus bars (e.g., 413, 415) spaced apart from each other and fixed to the panel; and (d) guiding structures (e.g., 433) extending from a surface of the first wall. The guiding structures (a) engage with chassis modules and (b) prevent the received chassis modules from sliding into an adjacent receiving compartment.

In some embodiments, a spine (e.g., 400, 1000) of a chassis (e.g., electrical panel 100) includes: (a) a back panel (e.g., 411); (b) a side wall (e.g., 435) extending from an edge (e.g., 419) of the back panel; (c) two bus bars (e.g., 413, 415) that are spaced apart from each other, fixed to the back panel, and run parallel to the side wall; and (d) guide structures (e.g., 433) extending from the side wall and/or at fixed positions relative to the bus bars. The guide structures define receiving compartments (e.g., 437) for attaching chassis modules (e.g., 500, 600, 700, 900, 1100) across the two bus bars, and the receiving compartments are configured for field installation of the chassis modules.

In some embodiments, a spine (e.g., 400, 1000) of a chassis (e.g., electrical panel 100) includes: (a) a back panel (e.g., 411); (b) two bus bars (e.g., 413, 415) that are spaced apart from each other, fixed to the back panel, and run parallel to the side wall; and (d) guide structures (e.g., 433) located at fixed positions relative to the bus bars. The guide structures define receiving compartments (e.g., 437) for attaching chassis modules (e.g., 500, 600, 700, 900, 1100) across the two bus bars, and the receiving compartments are configured for field installation of the chassis modules.

In some embodiments, a spine (e.g., 400, 1000) of a chassis (e.g., electrical panel 100) includes: (a) a back panel (e.g., 411); (b) a side wall (e.g., 435) extending from an edge (e.g., 419) of the back panel; (c) two bus bars (e.g., 413, 415) that are spaced apart from each other, fixed to the back panel, and run parallel to the side wall; and (d) guide structures (e.g., 433) extending from the side wall. The guide structures define receiving compartments (e.g., 437) for attaching chassis modules (e.g., 500, 600, 700, 900, 1100) across the two bus bars. The receiving compartments are for field installation of the chassis modules. For each receiving compartment: the two bus bars contain a hole pattern for attachment of the chassis module to the two bus bars, and the side wall includes an opening (e.g., 435) to pass an electrical connection that provides data and/or power to the chassis module.

In some embodiments, a spine (e.g., 400, 1000) of a chassis (e.g., electrical panel 100) includes: (a) a back panel (e.g., 411); (b) two bus bars (e.g., 413, 415) spaced apart from each other and fixed to the back panel, each bus bar including holes along a length of the bus bar and aligned with holes on the other bus bar, where a set of aligned holes are configured to receive fasteners (e.g., bolts) that hold a chassis module in physical contact to the bus bars; (c) a wall (e.g., 407) raised from a first edge (e.g., 419) of the back panel and extending along the first edge. The wall includes cavities (e.g., 435) spaced along the length of the wall and at locations relative to holes of the bus bars.

In some embodiments, one or more (e.g., each) receiving compartment is additionally formed by a portion of a second wall (e.g., 409) raised from a second edge (e.g., 417) of the panel and extending along the second edge. Each receiving compartment may be additionally formed by one or more guiding structures extending from a surface of the second wall facing the first wall (e.g., 407).

The spine (e.g., 400, 1000) may further include a neutral bus bar (e.g., 429) or a ground bus bar (e.g., 431) fixed to a top surface of the wall (e.g., 407 or 409).

The guiding structures may be configured to engage with an outer surface of a chassis module (e.g., an outer surface of receiving element). For example, guiding structures are configured to engage with track indentations (e.g., 509, 609, 909) of chassis modules.

### Additional Module Examples

The below paragraphs provide additional descriptions of example modules. The modules described below may omit features referenced with respect to FIGS. 5-7, 9, and 11 and/or include features that are in addition to or alternative to the features referenced with respect to FIGS. 5-7, 9, and 11.

In some embodiments, a chassis module (e.g., 500, 600, 700, 900, 1100) for a chassis (e.g., a modular electrical panel 100) includes an insertion element (e.g., 501, 601, 701, 901) configured to slide into one of a plurality of receiving compartments (e.g., 437) of a spine (e.g., 400 or 1000) of the chassis. The insertion element includes: a first electrical contact (e.g., 510, 610, 910), a first hole (e.g., 542, 642, 942), a second electrical contact (e.g., 512, 612, 912), and a second hole (e.g., 540, 640, 940). The first contact is on a first side of the insertion element (e.g., on a first portion 505, 605, 905) and is configured to physically contact a first bus bar (e.g., 413) of the spine. The first hole is on the first side of the insertion element and may be configured to receive a first fastener (e.g., bolt or screw) that holds the first electrical contact in physical contact to the first bus bar. The second electrical contact is on a second side of the insertion element opposite the first side (e.g., on the second portion 507, 607, 907). The second electrical contact is configured to contact a second bus bar (e.g., 415) of the spine. The second hole is on the second side of the insertion element and is configured to receive a second fastener (e.g., bolt or screw) that holds the second electrical contact in physical contact to the second bus bar

In some embodiments, a chassis module (e.g., 500, 600, 700, 900, 1100) is configured for installation at any of a plurality of receiving compartments (e.g., 437) of a spine (e.g., 400 or 1000) of a chassis (e.g., 100). The spine includes two bus bars (e.g., 413, 415). The chassis module includes two bus bar contacts (e.g., 510, 512) and a port. The bus bar contacts are on a bottom of the chassis module (e.g., at a receiving element 501, 601, 901), where each of the two bus bar contacts physically contact the corresponding bus bar of the spine, and the bus bar contacts and the bus bars have (e.g., standard and/or repeating) hole patterns for attachment of the chassis module to the spine at the receiving compartment. The port is for attachment of a data and/or power connection to the chassis module. The port may be accessible after attachment of the chassis module to the spine (e.g., via holes (e.g., 435) in wall 407). In some embodiments (e.g., when the chassis module is a branch module (e.g., 600)), the chassis module includes attachment points (e.g., stab 611) for (e.g., eight) branch circuits, where the chassis module distributes electricity from the bus bars to the branch circuits.

### Additional Descriptions of Example Embodiments Part I

Additional example embodiments include:
Clause 1. A chassis module for a chassis, the chassis module comprising: an insertion element configured to slide into one of a plurality of receiving compartments of a spine of the chassis, the insertion element comprising: a first electrical contact on a first side of the insertion element and configured to physically contact a first bus bar of the spine, wherein the first side of the insertion element forms a first hole configured to receive a first fastener that holds the first electrical contact in physical contact to the first bus bar; and a second electrical contact on a second side of the insertion element opposite the first side, the second electrical contact configured to contact a second bus bar of the spine; wherein the second side of the insertion element forms a second hole configured to receive a second fastener that holds the second electrical contact in physical contact to the second bus bar.
Clause 2. A chassis module configured for installation at any of a plurality of receiving compartments of a spine of a chassis, the spine comprising two bus bars, the chassis module comprising: two bus bar contacts on a bottom of the chassis module, where each of the two bus bar contacts physically contact the corresponding bus bar of the spine, and the bus bar contacts and the bus bars have hole patterns for attachment of the chassis module to the spine at the receiving compartment; and a port for attachment of a data and/or power connection to the chassis module.
Clause 3. A chassis module for a chassis, the chassis module comprising: an insertion element configured to slide into one of a plurality of receiving compartments of a spine of the chassis, the insertion element comprising: a first electrical contact on a first side of the insertion element and configured to physically contact a first bus bar of the spine; and a second electrical contact on a second side of the insertion element opposite the first side, the second electrical contact configured to contact a second bus bar of the spine.
Clause 4. The chassis module of any of the previous clauses, wherein the chassis is an electrical panel, and the chassis module is an electrical component for the electrical panel.
Clause 5. The chassis module of any of the previous clauses, further comprising a port for attachment of a data and/or power connection to the chassis module.
Clause 6. The chassis module of clause 5, wherein the port is accessible for attachment of the data and/or power connection after the chassis module is at the receiving compartment.
Clause 7. The chassis module of any of the previous clauses, further comprising a first portion on the first side of the insertion element, the first portion including the first electrical contact, the first portion configured to receive the first bus bar of the spine and directly couple to the first bus bar.
Clause 8. The chassis module of clause 7, further comprising a second portion on the second side of the insertion element, the second portion including the second electrical contact, the second portion configured to receive the second bus bar of the spine and directly couple to the second bus bar.
Clause 9. The chassis module of clause 8, wherein the insertion element further comprises a third portion between the first portion and the second portion, the third portion configured to, when the insertion element is in one of the plurality of receiving compartments, be between the first bus bar and the second bus bar of the spine.
Clause 10. The chassis module of any of the previous clauses, wherein the first electrical contact is arranged to physically contact a top surface of the first bus bar of the spine when the insertion element is in one of the plurality of receiving compartments.
Clause 11. The chassis module of any of the previous clauses, wherein the insertion element further comprises: a track indentation configured to engage with a guiding structure of the spine (a) to guide placement of the insertion element into one of the plurality of receiving compartments and (b) to retain the insertion element in the one of the plurality of receiving compartments after placement.
Clause 12. The chassis module of clause 11, wherein the track indentation extends along a sliding direction of the receiving compartment.
Clause 13. The chassis module of clauses 11 or 12, wherein the track indentation is part of an outer surface of the insertion element.
Clause 14. The chassis module of clauses 8 or 9, wherein the first portion and the second portion each form a hole configured to receive a fastener that fastens the insertion element to the respective bus bar.
Clause 15. The chassis module of any of the previous clauses, wherein the insertion element further comprises: a first clip mechanism on the first side of the insertion element, the first clip mechanism configured to engage with a first portion of the spine to hold the first electrical contact in physical contact to the first bus bar; and/or a second clip mechanism on the second side of the insertion element, the second clip mechanism configured to engage with a second portion of the spine to hold the second electrical contact in physical contact to the first bus bar.
Clause 16. The chassis module of any of the previous clauses, wherein the insertion element further comprises: a first protrusion on the first side of the insertion element, the first protrusion configured to engage with a first clip mechanism of the spine to hold the first electrical contact in physical contact to the first bus bar; and/or a second protrusion on the second side of the insertion element, the second protrusion configured to engage with a second clip mechanism of the spine to hold the second electrical contact in physical contact to the second bus bar.
Clause 17. The chassis module of any of the previous clauses, wherein the insertion element further comprises: a first magnet on or in the first side of the insertion element, the first magnet arranged to attract a second magnet on or in a first portion of the spine to hold the first electrical contact in physical contact to the first bus bar; and/or a third magnet on or in the second side of the insertion element, the third magnet arranged to attract a fourth magnet on or in a second portion of the spine to hold the second electrical contact in physical contact to the second bus bar.
Clause 18. The chassis module of any of the previous clauses, wherein the insertion element further comprises: a first pogo pin coupled to the first side of the insertion element and configured to electrically connect the first electrical contact to the first bus bar; and/or a second pogo pin coupled to the second side of the insertion element and configured to electrically connect the second electrical contact to the second bus bar.
Clause 19. The chassis module of any of the previous clauses, wherein: the chassis is an electrical panel; the chassis module is an electrical component for the electrical panel; and the chassis module is a mains module that connects main feeder wires to the electrical panel.
Clause 20. The chassis module of clause 19, wherein the mains module comprises at least one of: a main breaker for the electrical panel; or a microgrid interconnection device.
Clause 21. The chassis module of clauses 19 or 20, wherein the mains module is configured to provide overcurrent protection and a disconnect for the electrical panel.
Clause 22. The chassis module of any of clauses 1-16, wherein: the chassis is an electrical panel; the chassis module is an electrical component for the electrical panel; and the chassis module is a branch module configured to manage a set of one or more branch circuits.
Clause 23. The chassis module of clause 22, wherein the branch module includes electrical stabs for branch circuits, wherein the branch module is configured to distribute electricity from the bus bars to the branch circuits.
Clause 24. The chassis module of clause 23, wherein the electrical stabs are configured to engage with overcurrent circuit breakers.
Clause 25. The chassis module of any of clauses 22-24, wherein the insertion element is part of a housing that houses components of the chassis module, wherein the electrical stabs protrude through the housing.
Clause 26. The chassis module of clause 25, wherein components in the housing of the insertion element include: a current sensor; a relay for each branch circuit; at least a portion of an electrical stab for each branch circuit; and a printed circuit board.
Clause 27. The chassis module of any of clauses 22-26, wherein the branch module further includes a set of indicators that indicate relay states of the branch module.
Clause 28. The chassis module of clause 27, wherein the set of indicators includes an indicator for each branch circuit that the branch module is configured to manage.
Clause 29. The chassis module of clauses 27 or 28, where an indicator of the set includes: a light source; and a light pipe that extends away from the light source, the light pipe configured to direct light from the light source to a front face of the chassis module.
Clause 30. The chassis module of clause 29, wherein the light pipe is substantially parallel to an electrical stab protruding through a housing of the chassis module, the electrical stab configured to engage with an overcurrent circuit breaker.
Clause 31. The chassis module of clauses 29 or 30, wherein the light pipe is configured to direct light through a hole in dead front positioned over the chassis module.
Clause 32. The chassis module of any of clauses 29-31, wherein light emitted from the light source illuminates through a dead front positioned over the chassis module.
Clause 33. The chassis module of any of clauses 29-32, wherein the light source is configured to emit light corresponding to a state of a relay of the chassis module.
Clause 34. The chassis module of any of clauses 22-33, wherein a dead front is positioned over a top surface of the chassis module.
Clause 35. The chassis module of clause 34, wherein the dead front includes modular dead front panels configured to be individually removed.
Clause 36. The chassis module of clause 35, wherein a modular dead front panel is aligned with a slot configured to receive an overcurrent electrical panel.
Clause 37. The chassis module of clauses 35 or 36, wherein a modular dead front panel is aligned with an electrical stab protruding through a housing of the chassis module, the electrical stab configured to engage with an overcurrent circuit breaker.
Clause 38. The chassis module of any of clauses 35-37, wherein a modular dead front panel includes a tab configured to engage with a deadfront of the electrical panel.
Clause 39. The chassis module of any of clauses 35-38, wherein a modular dead front panel includes a support structure extending downward to a front surface of the chassis module.
Clause 40. The chassis module of any of clauses 34-39, wherein the dead front forms holes configured to allow light from light indicators to pass through the dead front.
Clause 41. The chassis module of any of clauses 1-16, wherein: the chassis is an electrical panel; the chassis module is an electrical component for the electrical panel; and the chassis module is a lug module configured to electrically couple a first feeder wire to the first bus bar and a second feeder wire to the second bus bar.
Clause 42. The chassis module of clause 41, wherein the lug module comprises: a first wire lug configured to electrically couple a first feeder wire to the first electrical contact; and/or a second wire lug configure to electrically couple a second feeder wire to the second electrical contact.
Clause 43. The chassis module of clause 42, wherein the lug module further comprises: an auxiliary port configured to provide electrical access to the first wire lug.
Clause 44. The chassis module of clauses 42 or 43, wherein the first wire lug and the second wire lug are at least partially housed in the insertion element.
Clause 45. The chassis module of any of clauses 42-44, wherein the lug module further comprises: a first current sensor arranged to measure current between the first wire lug and the first electrical contact; and/or a second current sensor arranged to measure current between the second wire lug and the second electrical contact.
Clause 46. The chassis module of clause 45, wherein the first current sensor and the second current sensor are at least partially housed in the insertion element.
Clause 47. The chassis module of clauses 45 or 46, wherein the first current sensor is a first current transformer positioned around a first connector that connects the first wire lug to the first electrical contact, and the second current sensor is a second current transformer position around a second connector that connects the second wire lug to the second electrical contact.
Clause 48. The chassis module of any of clauses 45-47, wherein the lug module further comprises a top cover that couples to the insertion element, where the top cover and the insertion element house: the first wire lug; the second wire lug; the first current sensor; the second current sensor; at least a portion of the first electrical contact; and at least a portion of the second electrical contact.
Clause 49. The chassis module of any of the previous clauses, wherein the insertion element further comprises an air duct configured to direct air flow through the chassis module.
Clause 50. The chassis module of clause 49, wherein the air duct is configured to direct air from a third side of the insertion element to a fourth side of the insertion element.
Clause 51. The chassis module of clause 50, wherein the third and fourth sides of the insertion element are different from the first and second sides of the insertion element.
Clause 52. The chassis module of clauses 50 or 51, wherein a path of air through the air duct from the third side to the fourth side is substantially parallel to a length of the first bus bar.
Clause 53. The chassis module of any of clauses 49-52, wherein an end of the air duct is arranged, such that when an additional chassis module is positioned in an adjacent receiving compartment of the plurality of receiving compartments, the end of the air duct is aligned with an air duct of the additional chassis module.
Clause 54. The chassis module of any of clauses 49-53, further comprising one or more fins in the insertion element, the fins configured to direct air flow of the air duct to internal components of the chassis module.
Clause 55. The chassis module of any of clauses 1-16, wherein: the chassis is an electrical panel; the chassis module is an electrical component for the electrical panel; and the chassis module is a panel control module configured to manage control of the electrical panel.
Clause 56. The chassis module of clause 55, wherein the panel control module comprises a user interface bar on a top surface that enables a user to interact with the electrical panel.
Clause 57. The chassis module of clauses 55 or 56, wherein the panel control module comprises a fan module receiving compartment for a fan module.
Clause 58. The chassis module of clause 57, wherein the panel control module comprises the fan module in the fan module receiving compartment.
Clause 59. The chassis module of clauses 57 or 58, wherein the panel control module further comprises an air duct configured to direct air flow from the fan module receiving compartment to a side of the panel control module.
Clause 60. The chassis module of clause 59, wherein an end of the air duct is arranged, such that when an additional chassis module is positioned in an adjacent receiving compartment of the plurality of receiving compartments, the end of the air duct is aligned with an air duct of the additional chassis module.
Clause 61. The chassis module of any of clauses 55-60, wherein the panel control module comprise mounting elements configured to mount a gateway module to a top surface of the panel control module, wherein the gateway module is configured to be a site controller for a building.
Clause 62. A dead front panel for an electrical panel, the dead front including: a first panel; and a first set of two or more modular dead front panels attached to a first side of the first panel and extending away from the first side of the first panel.
Clause 63. The dead front panel of clause 62, further comprising: a second set of two or more modular dead front panels on a second side of the first panel opposite the first side.
Clause 64. The dead front panel of clauses 62 or 63, wherein the first panel forms holes configured to allow light from light indicators to pass through the first dead front panel.
Clause 65. The dead front panel of any of clauses 62-64, wherein a dead front is positioned over a front surface of the electrical panel.
Clause 66. The dead front panel of any of clauses 62-65, wherein the dead front panel is configured to couple to a front surface of the electrical panel.
Clause 67. The dead front panel of clause 66, wherein the first panel forms a hole configured to receive a fastener that couples the dead front panel to the front surface of the electrical panel.
Clause 68. The dead front panel of any of clauses 62-67, wherein modular dead front panels of the first set are configured to be individually removed.
Clause 69. The dead front panel of any of clauses 62-68, wherein a modular dead front panel of the first set is aligned with a slot configured to receive an overcurrent electrical panel.
Clause 70. The dead front panel of any of clauses 62-69, wherein a modular dead front panel of the first set is aligned with an electrical stab protruding through a housing of an electrical module of the electrical panel, the electrical stab configured to engage with an overcurrent circuit breaker.
Clause 71. The dead front panel of any of clauses 62-70, wherein a modular dead front panel of the first set includes a tab configured to engage with a second deadfront of the electrical panel.
Clause 72. The dead front panel of any of clauses 62-71, wherein a modular dead front panel of the first set includes a support structure extending downward to a front surface of the electrical panel.
Clause 73. An electrical panel with an air duct configured to direct air flow through the electrical panel.
Clause 74. The electrical panel of clause 73, wherein a path of air through the air duct of the electrical panel is substantially parallel to length of a bus bar of the electrical panel.
Clause 75. The electrical panel of clauses 73 or 74, wherein the air duct directs air flow through a branch circuit module configured to distribute electricity from bus bars to branch circuits.
Clause 76. The electrical panel of any of clauses 73-75, wherein the air duct comprises a set of aligned air ducts of modules of the electrical panel.
Clause 77. The electrical panel of clause 76, wherein an air duct of a module of the electrical panel is configured to direct air flow through the module.
Clause 78. The electrical panel of clause 77, wherein the air duct of the module is configured to direct air from a first side of the module to a second side of the module.
Clause 79. The electrical panel of clause 78, wherein the air duct of the module comprises one or more fins configured to direct air to internal components of the chassis module.
Clause 80. A spine of a chassis, the spine comprising: a back panel; a side wall extending from an edge of the back panel; two bus bars that are spaced apart from each other, fixed to the back panel, and run parallel to the side wall; and guiding structures extending from the side wall, the guiding structures defining receiving compartments for attaching chassis modules across the two bus bars, wherein the receiving compartments are configured for field installation of the chassis modules and for each receiving compartment: the two bus bars contain a hole pattern for attachment of the chassis module to the two bus bars, and the side wall includes an opening to pass an electrical connection that provides data to the chassis module.
Clause 81. A spine of a chassis, the spine comprising: receiving compartments configured to receive chassis modules, each receiving compartment formed by: a portion of a panel; a portion of a wall raised from a first edge of the panel and extending along the first edge; portions of two bus bars spaced apart from each other and fixed to the panel; and one or more guiding structures extending from a surface of the first wall, the guiding structures configured to (a) engage with chassis modules and (b) prevent the received chassis modules from sliding into an adjacent receiving compartment.
Clause 82. The spine of clause 81, wherein the chassis is an electrical panel.
Clause 83. The spine of clauses 81 or 82, wherein the receiving compartments are for attaching chassis modules across the two bus bars.
Clause 84. The spine of any of clauses 81-83, wherein the receiving compartments are configured for field installation of the chassis modules.
Clause 85. The spine of any of clauses 81-84, wherein the guiding structures are at fixed positions relative to the bus bars.
Clause 86. The spine of any of clauses 81-85, wherein the two bus bars run parallel to each other.
Clause 87. The spine of any of clauses 81-86, wherein each receiving compartment is additionally formed by a portion of a second wall raised from a second edge of the panel and extending along the second edge.
Clause 88. The spine of clause 87, wherein each receiving compartment is additionally formed by one or more guiding structures extending from a surface of the second wall facing the first wall.
Clause 89. The spine of any of clauses 81-88, wherein the spine further comprises a neutral bus bar or a ground bus bar fixed to a top surface of the wall.
Clause 90. The spine of any of clauses 81-89, wherein each bus bar includes holes along a length of the bus bar and aligned with holes on the other bus bar, and a set of aligned holes are configured to receive fasteners that hold a chassis module in physical contact to the bus bars.
Clause 91. The spine of any of clauses 81-90, wherein the two bus bars contain a hole pattern for attachment of the chassis modules to the two bus bars.
Clause 92. The spine of any of clauses 81-91, wherein the wall includes cavities spaced along the length of the wall and at locations aligned with the receiving compartments.
Clause 93. The spine of any of clauses 81-92, wherein the guiding structures are tabs.
Clause 94. The spine of any of clauses 81-93, wherein the guiding structures engage with an outer surface of a chassis module.
Clause 95. The spine of clause 94, wherein guiding structures are configured to engage with track indentations of chassis modules.
Clause 96. A spine of a chassis, the spine comprising: a back panel; two bus bars spaced apart from each other and fixed to the back panel, each bus bar including holes along a length of the bus bar and aligned with holes on the other bus bar, a set of aligned holes configured to receive fasteners that hold a chassis module in physical contact to the bus bars; and a wall raised from a first edge of the panel and extending along the first edge, the wall including cavities spaced along the length of the wall and at locations relative to holes of the bus bars.
Clause 97. The spine of clause 96, further comprising one or more guiding structures extending from a surface of the wall, the guiding structures configured to (a) engage with chassis modules and (b) prevent the received chassis modules from sliding into an adjacent receiving compartment.
Clause 98. The spine of clause 97, wherein the guiding structures are tabs.
Clause 99. The spine of any of clauses 96-98, further comprising guiding structures extending from the wall, the guiding structures defining receiving compartments for attaching chassis modules across the two bus bars, wherein the receiving compartments are configured for field installation of the chassis modules and for each receiving compartment: the two bus bars contain a hole pattern for attachment of the chassis module to the two bus bars, and the wall includes an opening to pass an electrical connection that provides data to the chassis module.
Clause 100. A gateway module for an electrical panel of a building, the gateway module configured to be a site controller for a building.
Clause 101. The gateway module of clause 100, wherein the gateway module includes a housing configured to physically couple to the electrical panel.
Clause 102. The gateway module of clause 101, wherein the housing is configured to physically mount to the electrical panel.
Clause 103. The gateway module of clause 102, wherein the housing is configured to physically mount to a modular electrical component of the electrical panel.
Clause 104. The gateway module of clause 103, wherein the housing includes a first side for ports (e.g., configured to hold ports) for cables to connect to the gateway module.
Clause 105. The gateway module of clause 104, wherein the housing further includes a recess (e.g., recess 1215) on a second side opposite the first side, the recess configured to engage with a protrusion (e.g., tooth 1220) of a receiving compartment on modular electrical component of the electrical panel.
Clause 106. The gateway module of clause 103, wherein the modular electrical component of the electrical panel is a panel control module configured to manage control of the electrical panel.
Clause 107. The gateway module of clauses 103 or 106, wherein the modular electrical component is configured to slide into a receiving compartments of a spine of the electrical panel, wherein the spine includes a plurality of receiving compartments.
Clause 108. The gateway module of clause 107, wherein the modular electrical component comprises: a first electrical contact on a first side of the insertion element and configured to physically contact a first bus bar of the spine; and/or a second electrical contact on a second side of the insertion element opposite the first side, the second electrical contact configured to contact a second bus bar of the spine.
Clause 109. The gateway module of any of clauses 101-108, wherein the housing houses components of the gateway module comprising: a set of one or more processors, a computer-readable storage medium, and a set of one or more antennas.
Clause 110. The gateway module of any of clauses 101-109, wherein the gateway module is configured to communicate with two or more electrical panels of the building.

### Additional Descriptions of Example Embodiments Part II

This section describes additional example embodiments. Any features that are described as essential, important, or otherwise implied to be required should be interpreted as only being required for that embodiment and are not necessarily included in other embodiments.

Some embodiments relate to electrical panels, components of electrical panels, and components related to electrical panels (e.g., a standalone gateway). The panels may be referred to as “Span electrical panels.” The panels may be modular with field swappable component (e.g., via bolted joints), high heat dissipation capabilities, and/or a panel to panel/inter-module communication system. Among other advantages, the electrical panel may:
(i) be able to communicate with other electrical panels (e.g., transfer data or operation instructions);
(ii) be cheaper to manufacture or install than conventional panels;
(iii) have improved heat dissipation (e.g., less fan usage than conventional panels);
(iv) have modularity and have field swappabilty (e.g., to address failures in the field, to upgrade modules, and to enable rightsized installation according to the needs of the homeowner);
(v) be installed by a single person;
(vi) enable factory reuse of modules across multiple panel sizes;
(vii) include additional indicators (e.g., visual indicators) over conventional panels;
(viii) include additional connection ports over conventional panels;
(ix) include additional safety features over conventional panels; and
(x) have improved build quality and reliability over conventional panels.

Various aspects of electrical panels are described below. Any one aspect may be combined with or alternative to one or more other aspects.

### A. Spine

### A.1 Spine Module Connection

Description: Ability for service technicians and electricians to quick-disconnect modules and replace with updated versions that may have additional functionality. Also facilitates quick service or RMAs. Included in this are novel solutions to heat rejection of heat generating components.

The spine module connection is an improvement over conventional backplate designs because service technicians and electricians can more quickly disconnect modules and replace them with updated versions that have additional functionality. Thus, quick disconnections result in lower installation and maintenance costs—which are significant barriers to adoption of electrification--and lower part replacement costs compared to non-modular designs.

Construction and module mounting mechanism enables future proofing of modules, or multiples of modules. Module mounting mechanism and construction does not preclude adjusting the width of the module size to accommodate future designs.

Features include: a branch busbar with active features, heat rejection through a bolted electrical connection, captive screws with a torque driver enable consistent, safe connections onto high-voltage busswork, and ability to configure a panel with the modules that meet the needs of the installation site has never been done.

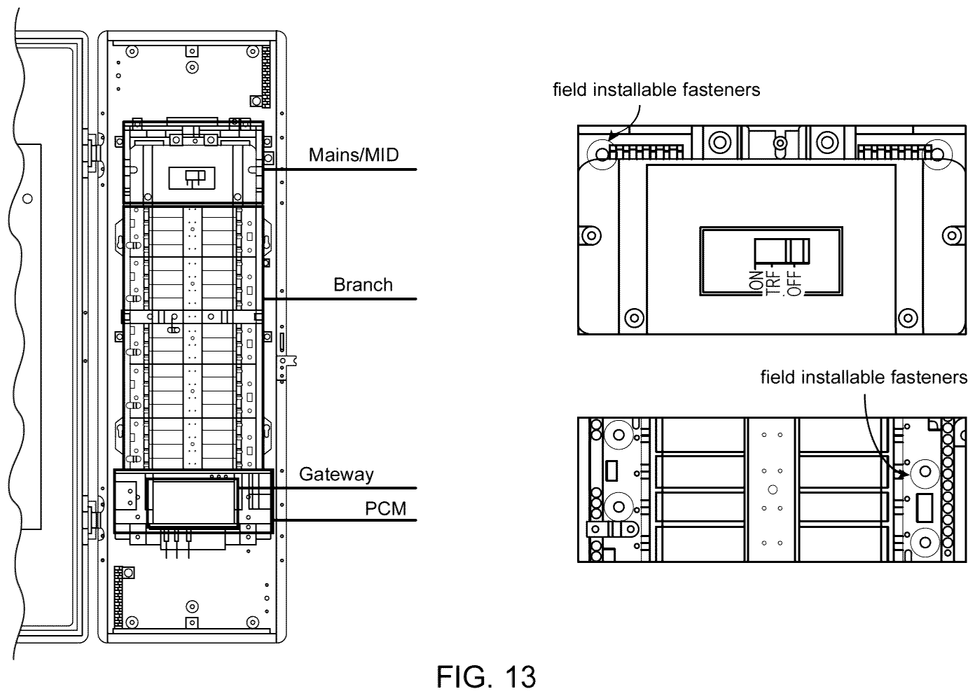

FIG. 13 (left) shows various module mounting locations, with outlines of individual modules.

FIG. 13 (right) shows mounting points, in this case standard fasteners bolted directly into the L1/L2 spine busbars. Certain embodiments of the modules may or may not use fasteners at all and rely on spring loaded clips in place of screw fasteners.
A.2 Molded Spine Assembly

Description: A plastic housing that holds the line side busbars and any other conductors (e.g., ground and neutral). The assembly may also hold the low voltage signal conductors that are used to move data and communications throughout the panel. Certain embodiments of this plastic may be manufactured using overmolding, may be an injection molded 2-part plastic clamshell, or may be manufactured using heat staking. The busbars (neutral, L1, L2, L3, ground) may be fastened to the spine assembly using heat staking, snap-features, or fasteners. Overmolding may couple the heat from the busbars to the spine. Further, the spine is removable and ensures the assembly can easily be placed into and removed from the enclosure.

Solution for: Reducing (e.g., minimizing) quantity of fasteners in spine assembly for ease of assembly. Improved thermals by eliminating thermal impedances between busbars and plastics, which can be improved further by using high thermally conductive resins. The removable spine assembly allows for single person installation by keeping the enclosure and spine each under a weight threshold (e.g., 50 lbs, the OSHA requirement for single person lift), and also allowing the lighter enclosure to be placed into a wall. It also allows the spine to drop into other enclosures.

The plastic housing described is advantageous because it may be manufactured using materials and manufacturing methods that are specifically designed for heat rejection, in order to create a thermal path for energy to leave the smart panel.

Other panels do not have as many high and low voltage parts to deal with and typically have more standard interfaces. By using this manufacturing method, the number of fasteners can be reduced (e.g., minimized) and the assembly can be manufactured on an automated assembly line.

Among other advantages, embodiments provide improved heat rejection and ease of installation from this construction method.

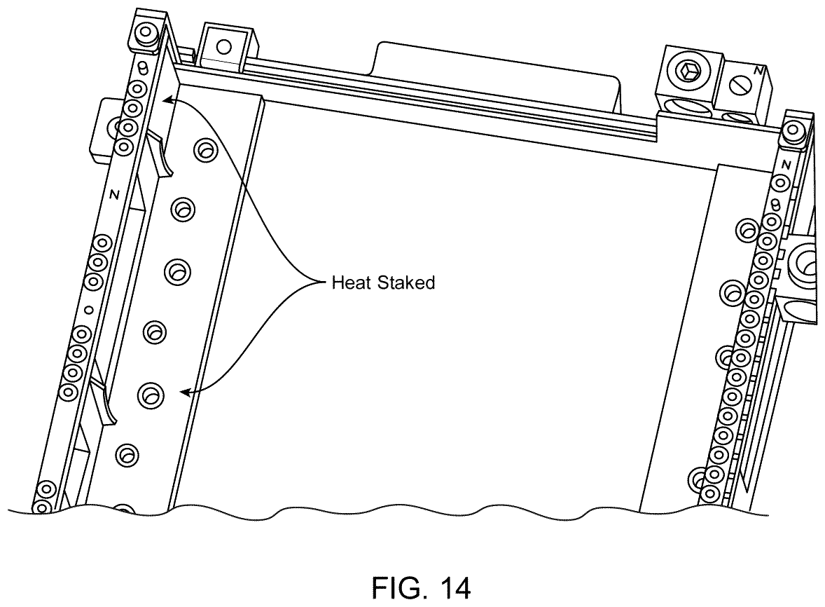

FIG. 14 shows heat stake insert connections to fasten the L1/L2 (bus bars) to the spine.
A.3 Spine Assembly Containing High and Low Voltage Connectors

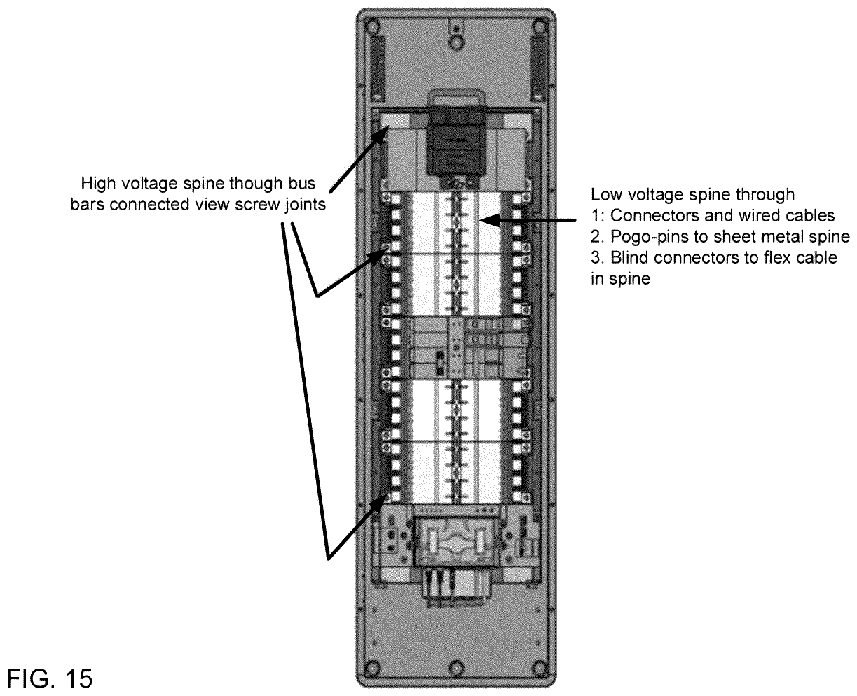

Description: A plastic housing that holds the line side busbars and any other conductors used (e.g., ground, neutral). The assembly may also hold the low voltage signal conductors that are used to move data and communications throughout the panel. This low voltage signal can be passed in between modules via a series of jumpers or “blind mate” connectors molded into the spine itself. For example, see FIG. 15.

Modules of the panel may be independently powered and communicate with one another. In order to achieve this, a “low voltage” connection may be used between modules that provide DC voltage and signals over a CAN bus interface (or the like). The physical communication hardware (connectors) can be incorporated into the spine assembly that already holds the L1, L2, and neutral busbars. This solves a pain point of installers because the low voltage connection can be tedious and is helpful (e.g., important) for the panel to function.

Incorporating additional functionality into a spine assembly that may just hold high-voltage bussing.

A.4 Gaps to Insert Pads of Thermal Interface Material (TIM), Graphite, or Other Conductive Materials to Increase Heat Transfer to the Enclosure While Electrically Insulating that Path to the Enclosure.

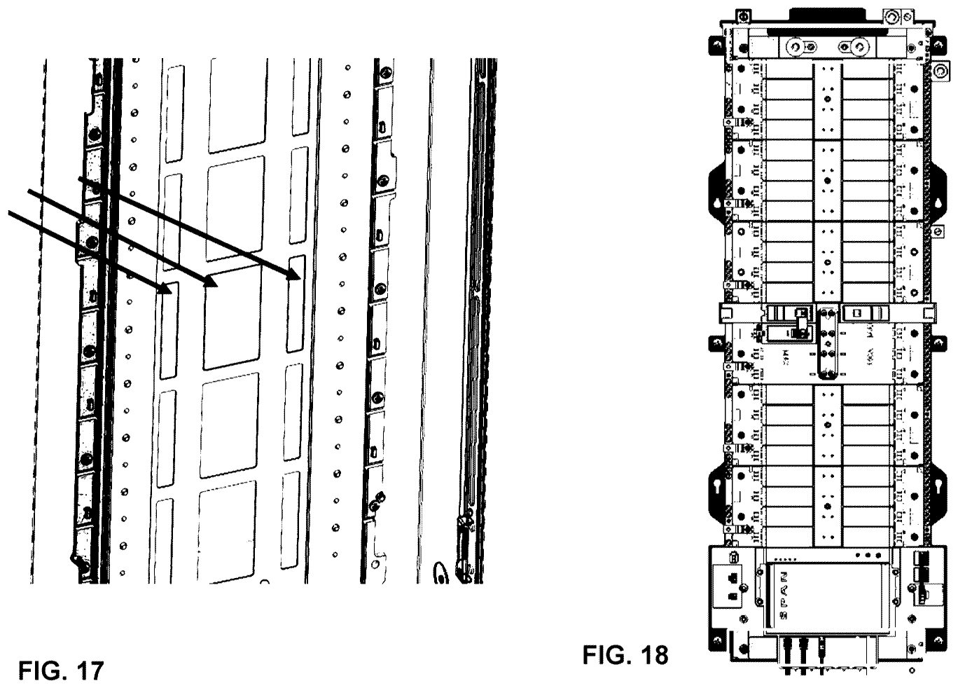

Description: Dedicated gaps in certain elements of the panel which can be filled with TIM (thermal interface material) or another material to enhance conductive heat transfer between the modules or spine to the enclosure. These gaps may be in a part of the spine assembly (e.g., see FIG. 17, where the arrows indicate locations for TIM), the modules, or in some other location.

The panel may generate a large amount of heat. The panel design can use the TIM and graphite sections described above to move excess heat out to the back of the enclosure where it can be rejected from the system using natural convection or other means. Rejecting excess heat may be a useful to protect the home from thermal events and to certify the panel.

Atypical use of TIM (usually to removable/module replaceable) and graphite.

Using graphite as a way to encapsulate the TIM, but still allow a good connection to the enclosure

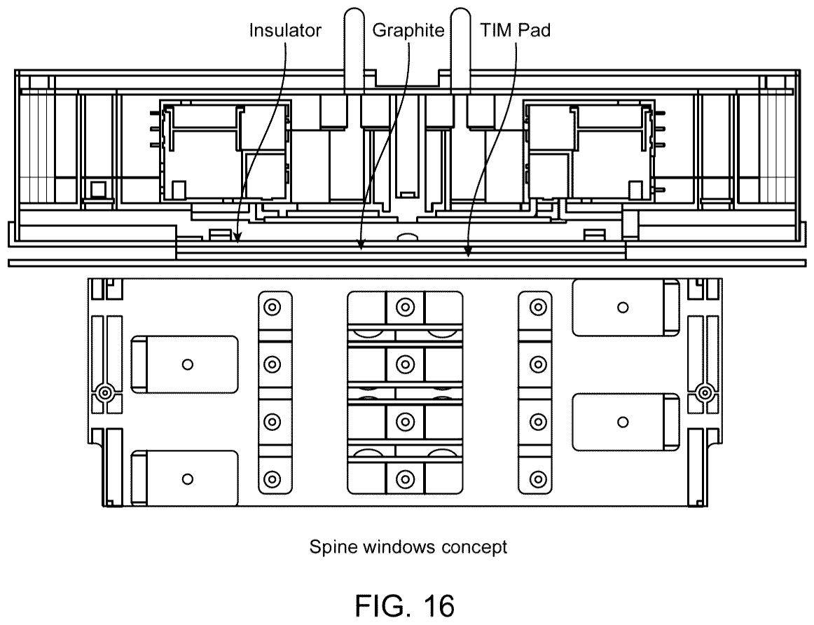

FIG. 16 shows a module with several layers of material in a “gap” underneath it. These layers of material are meant to enhance heat transfer to the enclosure body while maintaining electrical insulation (to not energize the entire panel or cause a short circuit).

A.5 1-inch Module Slot

Description: The design and modularity enables additional “1-inch modules” or other subcomponents to be incorporated into the system without requiring any field wiring by the installer. These smaller modules are advantageous in that they do not require homeowner interaction (proud of the dead front), and so the space can be efficiently utilized to provide increased functionality to the homeowner.

Solution for: 1.5″ module slots allow for solutions like feeder lugs (in the 48 circuit panel configuration), feed through lugs to a sub panel, whole home surge protection, active cooling or active heating.

Other panels do not have a spine or the ability to attach custom modules. Among other advantages, the installer or service technician may not have to perform field wiring in order to enable this functionality, since they have direct bolted access to the busbar(s). Example modules may add functionality like connectivity (antenna), thermal (add or remove heat), high voltage interface (extra power inputs to the system), whole home surge protection, etc.

This solves a problem that installers face because they typically have to use breaker locations (stabs) to add this functionality, but by setting aside a specific space for these add-on features, they can land more circuits in the panel and are less likely to use tandem breakers.

Dedicated location in an electrical panel for non-standard upgrades to the platform, beyond the standard interfaces that circuit breakers are designed to interface with (i.e. stabs.). These interfaces are advantageous in that they are behind the deadfront, and thus what may be attached to them is not something that will require any interaction from a homeowner or end user. These slots increase the overall utility of the platform.

It is not obvious to have entire modules/assemblies behind the deadfront that a homeowner will never interface with, but these modules/assemblies will still have full access to the busbars.

FIG. 18 shows where these 1.5″ module slots can attach to the busbars

FIG. 19 shows an example implementation of these modules, “Feedthrough lugs” which hold CTs and take the main feeders into the panel.

### B. Branch Module

### B.1 Module Stab Thermals

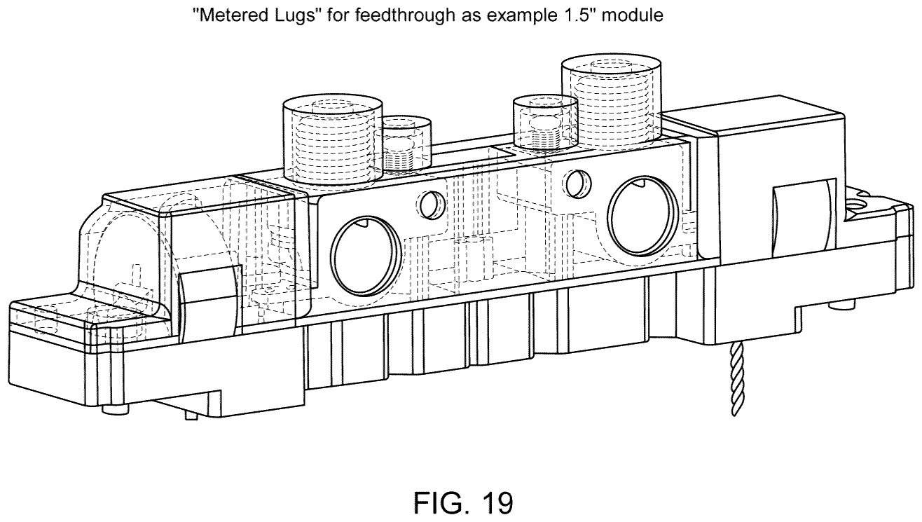

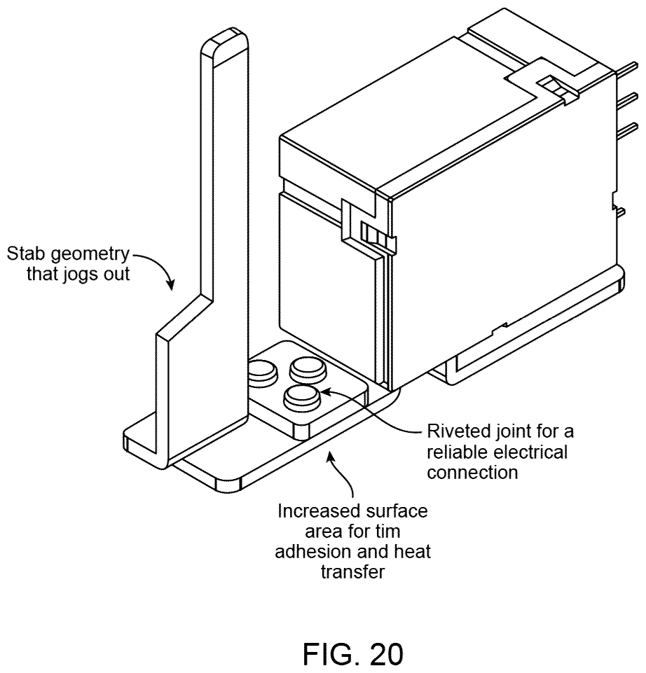

Description: Added metal mass to stabs to improve thermal conductivity. These stabs can connect to thermally conductive plastic to increase heat transfer performance. For example, see FIG. 20.

Typical electrical panels are designed to minimize stab geometry volume in order to save on cost and weight. However, that geometry is less massive and has less surface area and so is not capable of much heat transfer or thermal storage. Thus, this embodiment is counterintuitive in that it increases the stab mass and surface area in order to dissipate more heat.

There is no other stab geometry like this on the market.

Embodiments may include significant modifications to the typical stab and relay designs. In some cases, adds a rivet or braising operation to add metal thickness which reduces ohmic heating losses in addition to improving thermal storage.

### B.2 Thermal Gap Pads for Thermal Conductive, Electrically Insulating Path to the Branch Busbars.

Description: Gap pads from the stabs to the branch busbars. There is a thermally conductive path through the bolted connection, but this allows for additional non-electrically conductive paths to increase surface area for heat conduction.

Heat may accumulate on the conductor that sits in between the breaker and the relay. Embodiments provide a direct thermal path for heat to leave this system via conductive heat transfer.

Embodiments provide atypical use of getting multiple thermal paths into a busbar.

Allows heat from a single stab to be distributed across two busbars to spread heat further across the system.

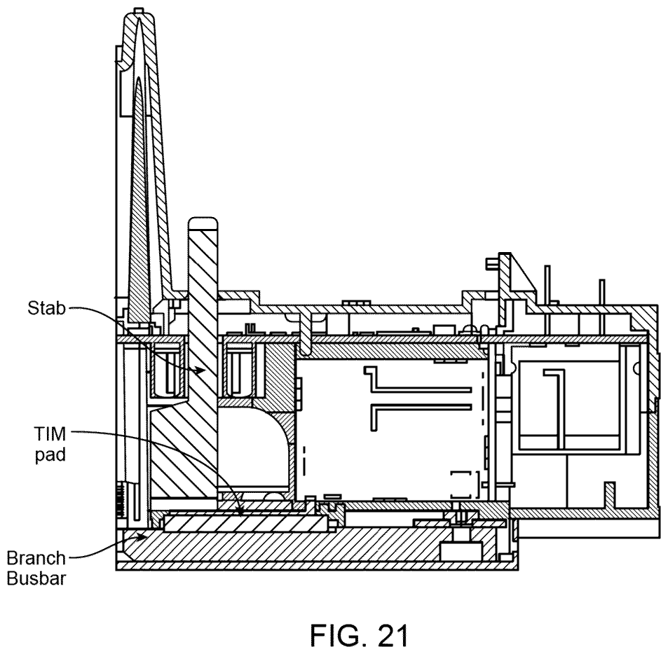

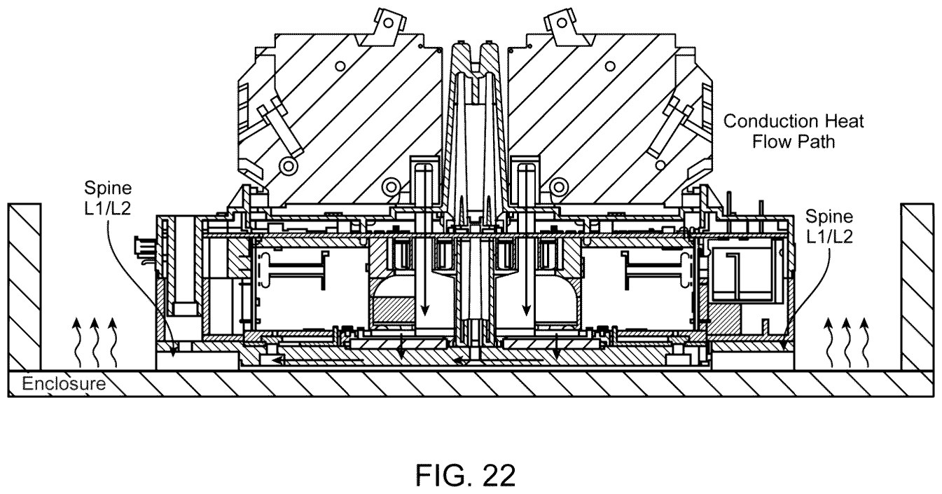

Examples can be seen in FIGS. 21 and 22.

### B.3 Induced Airflow Over Multiple Modules

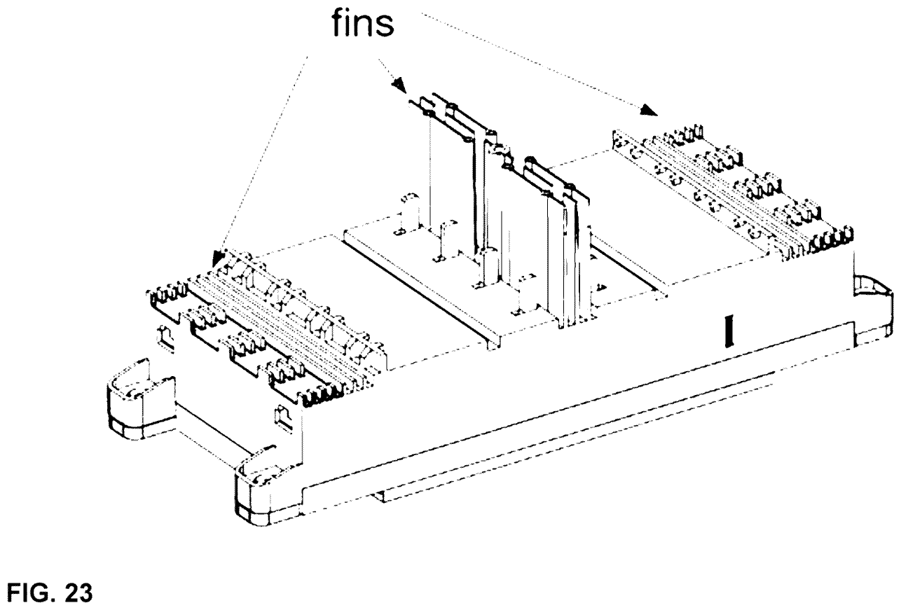

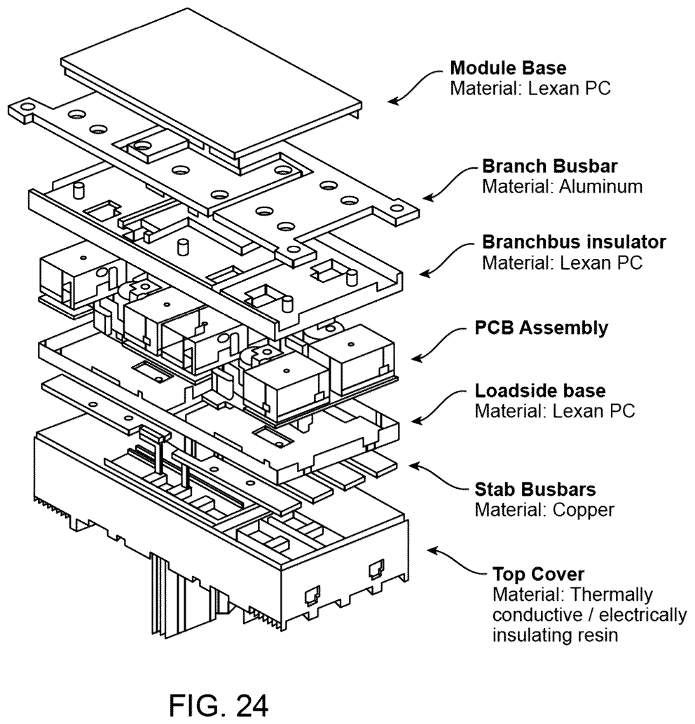

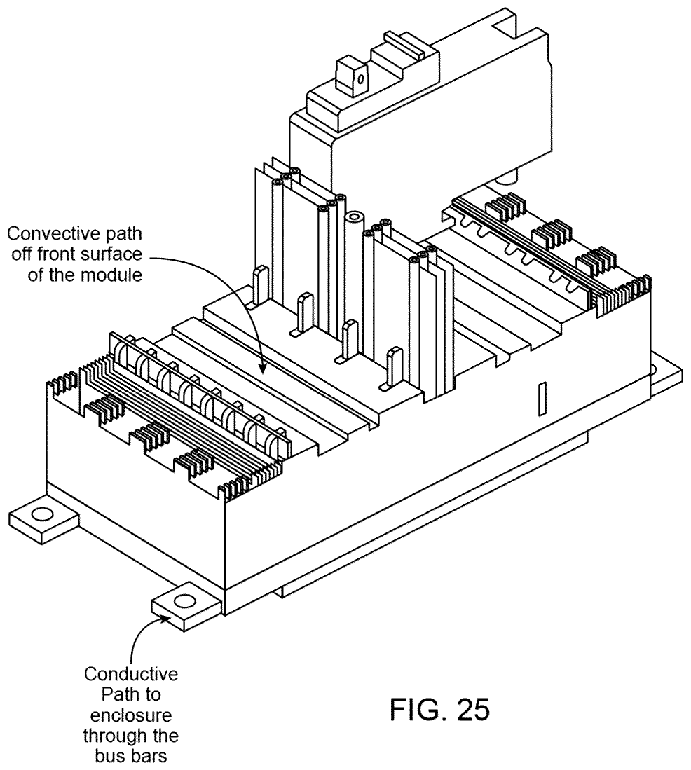

Description: Plastic electrically isolating fins used for conduction and natural convection. For example, see FIGS. 23-25.

Solution for: Removal of heat from modules

The induced airflow over modules is an improvement over existing panels because it uses a thermally conductive plastic with molded fins in it that, when oriented vertically in a panel can induce convective currents to increase the rate of heat transfer out of a module. These fins add marginal increase in cost but increase the surface area of the module while being oriented to act as air channels to duct air upwards.

Thermally conductive plastic resin is new. Due to the UL requirement banning the use of vents in panel enclosures, typically convection is a small part of the thermal spreading story, but this use of thermally conductive resins in some embodiments helps dissipate more than half the heat to internal ambient which makes it out of a larger area of the enclosure.

Among other advantages, plastic can be used for conduction (instead of metal to metal joints). Plastic fins use airflow effectively pulling heat from the front of the module which is usually not suitable for heat transport.

### B.4 Mechanism for Breaker Performance and Health Monitoring via Temperature and Voltage Sensing

Description: Sense the temperature of each individual stab by a direct connection to the stab inside the module. Additionally, can use the same connection to directly sense the voltage which can provide information on impedance creep or other field failures over time. These make the panel safer.

Solution for: Estimating lifetime of breakers and detecting defective field installs and protecting the device and field installed component. Can also be used to identify breaker failures and protect a home prior to an over temperature event. Enables fail safe for poor connections/connections that loosen in the field. Provides feedback on workmanship during field installation.

Many things can go wrong over the course of a typical panel installation, or over time in a home as components in an electrical panel age. These failures can be extraordinarily costly, can lead to fires, damage of home appliances, or electrical shock. By incorporating a PCB into the primary location of failure and outfitting it with sensors to measure voltage and temperature, potential safety and reliability concerns that homeowners may have can be reduced.

This also solves a problem installers have where if they swap out a module in the field, the system can verify that the connections are appropriately made.

Embodiments may be achieved using hardware components, like a spring loaded “stab clip” (diagrammed below) which may not require any manufacturing steps. It may also be achieved by other solutions like fasteners, soldering, and the like.

Field monitoring of each circuit to this extent is unprecedented. Field monitoring enables modularity, making field installable bolted joints safer.

Detecting voltage drop under load to provide an additional layer of protection. While torque specs are usually all that's required for testing a bolted joint at T0 and over the lifetime of the joint, the implementation of realtime feedback of module swaps and bolted joint connections in the field, is an atypical use of monitoring in electrical panels.

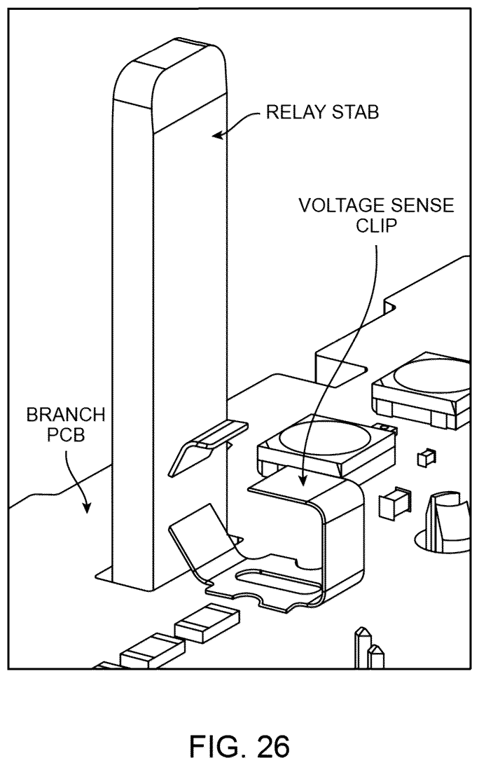

FIG. 26 shows the clip that attaches to the stabs (no fastener used) and allows for accurate voltage and temperature readings of the component.

### B.5 Internal Energy Storage (Short Term Energy Storage)

Description: Distributed energy storage allows for subsystems to fulfill duties. Relay actuation is possible even if components in the system fail. Additionally, separate switching devices and energy storage associated with two or more different line voltages conductors may be used as the interrupt current in single point faults.

Solution for: Voltage sags from the grid and disruption of AC due to poor bolted joint connections can fail safe.

In some embodiments, the electrical panel may be acting as the power control system for a house (e.g., in order to not overload a main breaker or utility service). Given this, certain low voltage failure modes may leave the panel in a state where it cannot perform its safety functions, if this happens it may be helpful to have available energy reserves to put the panel into a “safe” state.

Use of distributed capacitance allows for overall capacitance to be reduced. It enables a modular solution where (e.g., all) modules work together to protect themselves and hold over power to shut down safely in the case of a grid disruption.

### B.6 Module Deadfronts

Description: Deadfront may be divided into 1″, 2″, 4″, or 8″ module units, or other sized increments. This “mini deadfront” provides protection to the end user so that they are not exposed to any high voltage components. Modules may have different implementations of the module deadfront, depending on the geometry and construction of the module. The branch module deadfront interacts with the main deadfront with overlapping features that prevent the breaker from being removed by a homeowner (integrated breaker hold down functionality).

Solution for: Breaker removal by user in the field.

Typical electrical panels are only designed to hold standard circuit breakers of predefined dimensions. However, modular embodiments described herein enable flexibility for what will go into each module “slot”, be it circuit breakers, an energy storage device, or other power electronics. For homeowner touch safety, there may be no gaps in the deadfront and so a hardware solution exists to have each module unit have a dedicated deadfront to protect the end user after install.

Traditional panels breaker removal features come from one removable deadfront only, but this uses overlapping parts. Typical panels force you to install backfed breakers in only a few locations, where hold down features exist.

Use of a combined part to act as the dead front and breaker hold down feature together.

Module deadfront may also be used to hold light pipes to surface LED indication to the homeowner.

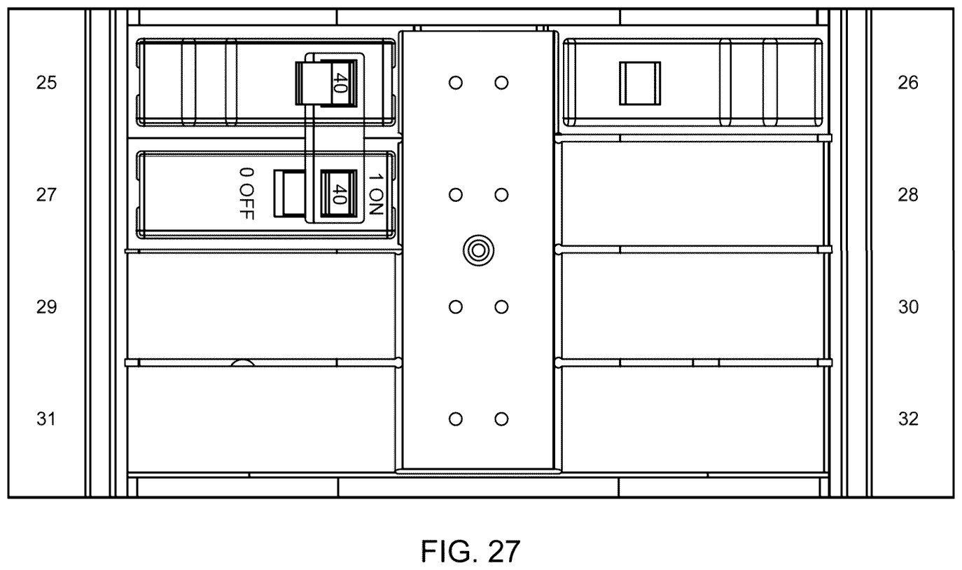

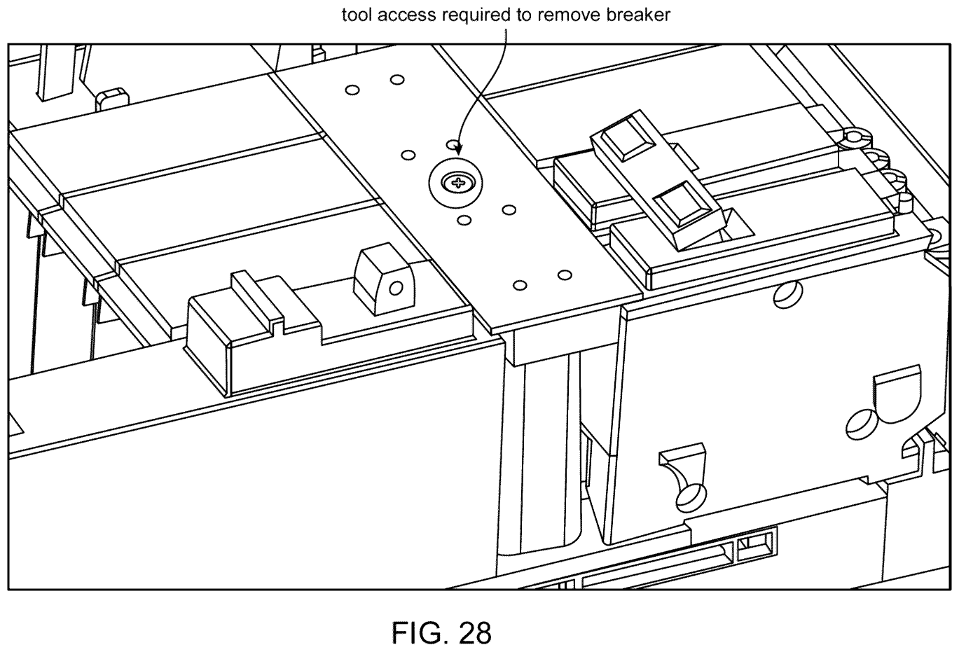

In FIGS. 27-28, the module deadfront covers up unused breaker spaces, holds the LEDs and light pipes that show circuit indication, and holds down breakers, in the case that they are backfed.

### B.7 LEDs for Relay State Indication

Description: Light sources (e.g., RGB LEDs) corresponding to each breaker can be used to show the relay state or provide other useful information to the homeowner or electrician. These LEDs may also be used to select specific breaker locations for more information or to identify faults in the panel. Users want a visible indication of what is going on the panel when they open it, especially in the event that connection to the mobile application is offline or poor. Certain embodiments may include lightpipe assemblies and enable all electrical components to be placed on a single PCBa.

Solution for: Informing the user on the status of (e.g., all) the circuits in their home at a given moment.

Conventional circuit breakers have an on and off switch that clearly indicates to users whether or not it is passing current to the house. However, embodiments include a relay behind this circuit breaker, and its state is not clearly visible to the user (e.g., installer or homeowner). To address this issue, the light sources may provide this relay state indication directly to the user, by the use of LEDs that are exposed proud of the deadfront.

These LEDs may also be used to cycle between available circuit breakers and change settings or override the state.

No electrical panel has relay indication features.

Canvas for additional UI features around throttled loads and scheduled circuits.

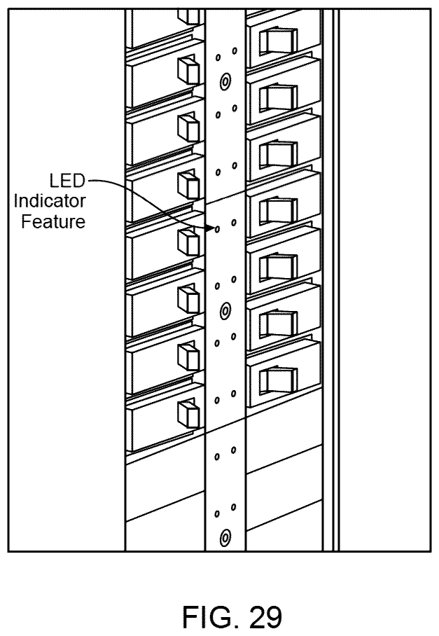

FIG. 29 shows possible location of relay state.

B.8 LED Indication of Relay State Integrated into the “Module Plastic Heatsink”

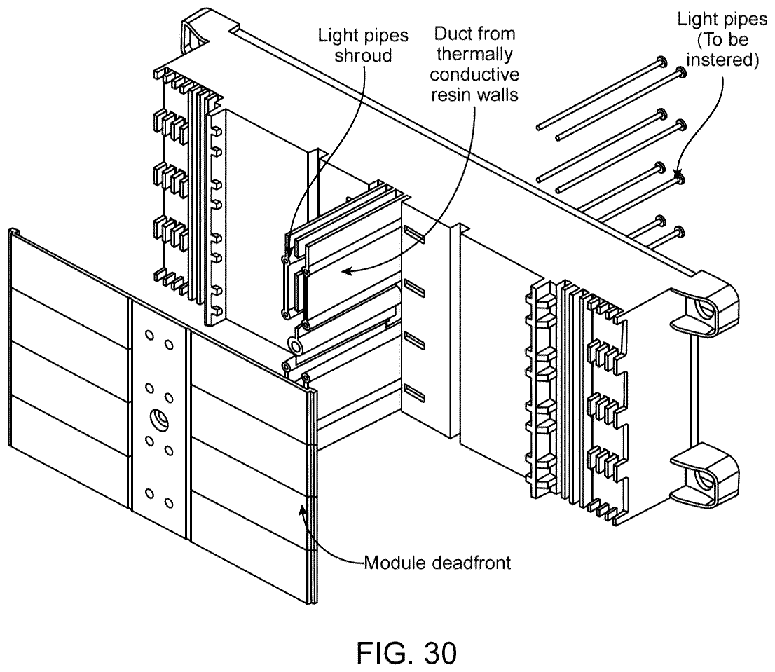

Description: The Light pipes are translucent for light to travel through them from the LED component to the user visible LED indication. For example, see FIG. 30. They are embedded in the black thermally conductive resin which acts as a shroud for light leakage. The ribs between light pipes create a channel of thermally conductive resin, which air can blow through to improved forced convection. The combination of these “fin walls” created by the light pipe allow for a continuous duct across the modules, where the module deadfront acts as the top of the duct. Additional, small openings in these fin walls allow for the air to vent out directly onto the hot breaker stabs.

Solution for: Light leakage prevention for light pipe. Improved thermals.

This is an optimization of the above, recognizing that a “light pipe” carrier may exist and therefore using this light pipe carrier to further increase the panels ability to dissipate heat.

Using light pipes as part of the thermal path in a system.

A combination part that serves the purposes of the light pipe shroud, thermal fin, fan duct, and LED indicator part is an atypical combination of parts that in this case, combines the functionality of the LEDs with the benefit of vastly improved system thermals.

### B.9 Module Deadfront as Air Duct for Active Cooling

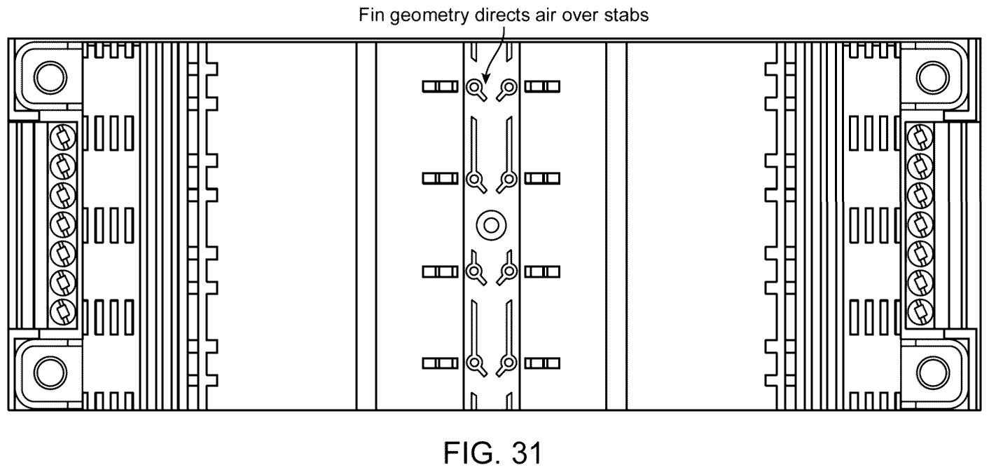

Description: Use the above module deadfront or lightpipe carriers as a duct to pass air directly to the locations where (e.g., the majority of the) heat is generated. For example, see FIG. 31.

Solution for: Thermals

This is an optimization for the above, recognizing that a “light pipe” carrier may exist and therefore using this light pipe carrier to further increase the panels ability to dissipate heat.

A literal airflow duct including optimized geometry.

### B.10 Using the Copper Front Spreader on Top of the Module Behind the Breakers for Heat Transport Below the Breakers.

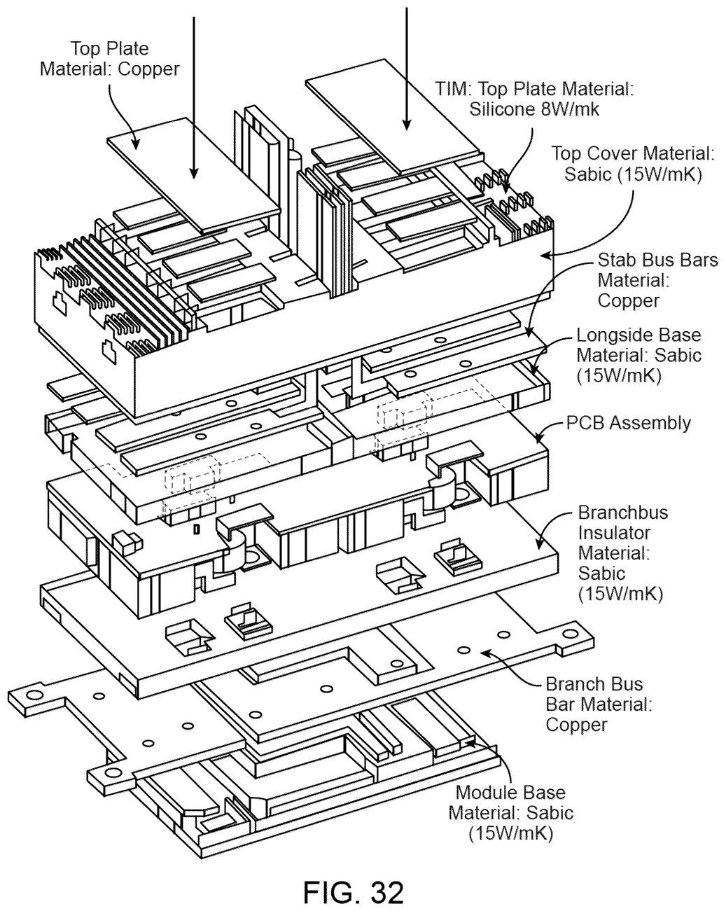

Description: Thermally conductive plate behind the breaker to spread heat from active to inactive breaker locations. For example, see FIG. 32.

Solution for: Thermal performance

Typical panels do not deal with thermals to this extent.

Distributed heat flux across both the front and back of the modules. The front heat path uses convection from internal airflow and the rear heat path uses conduction to the metal enclosure. Distribution drives larger temperature gradients which helps to dissipate heat more efficiently throughout the closed system.

B.11 Neutrals in the “C5 Design” Allow the Neutrals to be Brought in Toward the Center of the Panel to Help with Wiring Bend Radii.

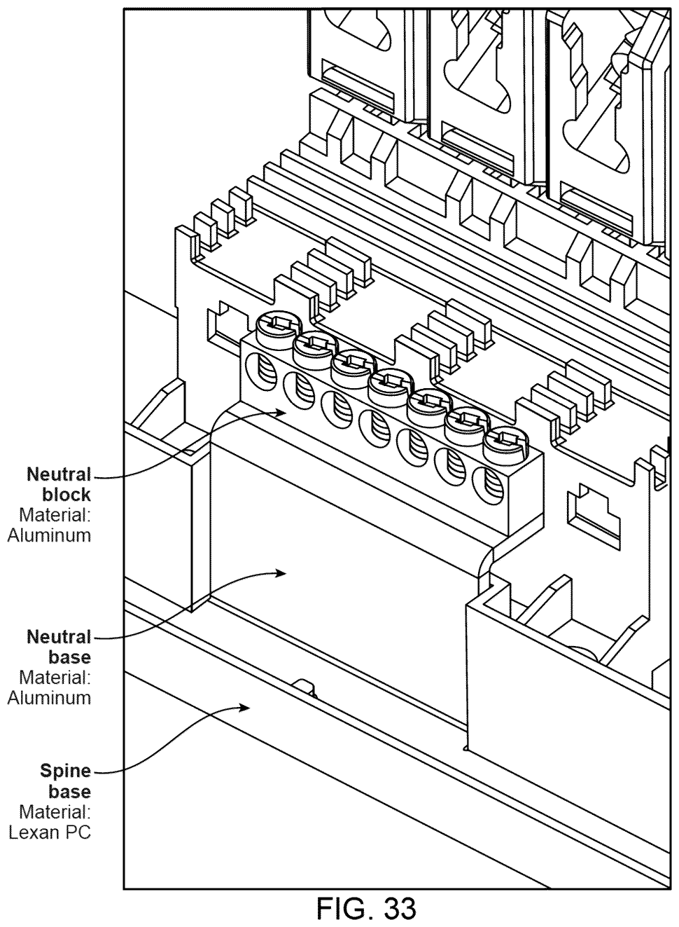

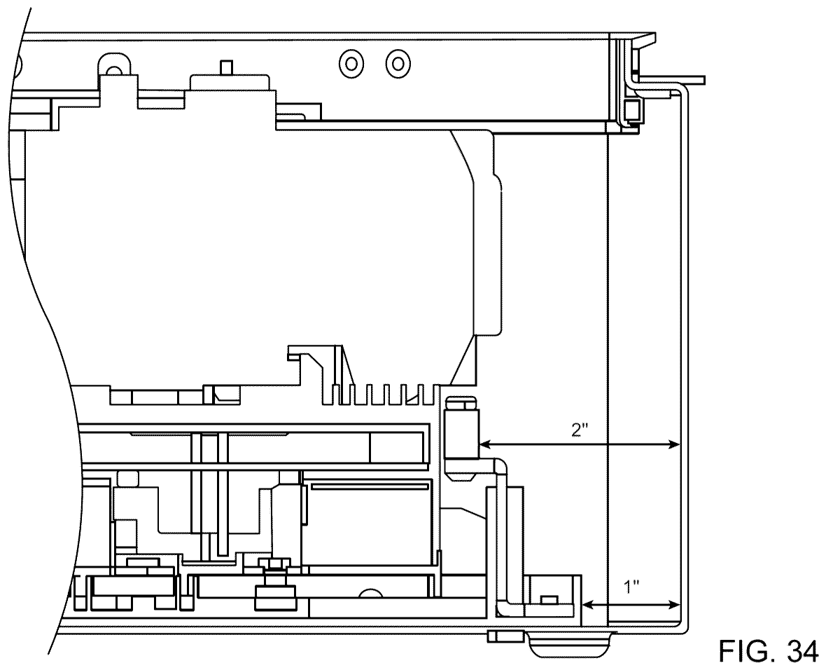

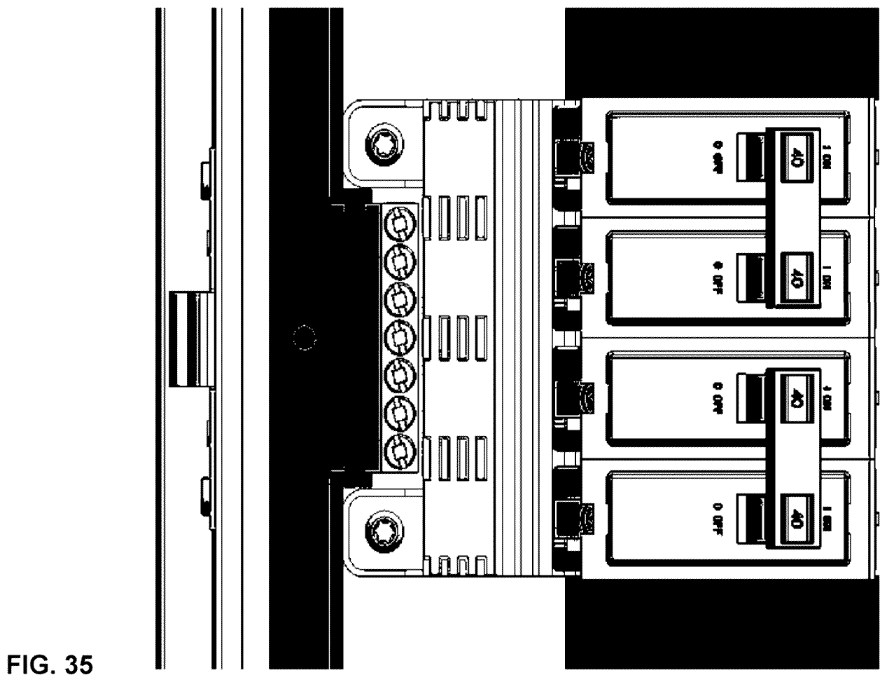

Description: Neutral blocks are fastened to a stamped part which maintains the neutral line through much of the perimeter of the backplate. Much of the live connection is covered/away from the field installer. For example, see FIGS. 33-35.

Solution for: Protection of the neutral line. Improved positioning of the breaker in a modular system.

Other neutral busbars are continuous and are not broken up in this way. This geometry allows them to be broken up.

Allows for much larger modules while still maintaining the minimum bend radius requirements for neutral wires.

Also allows for a series of alternate “neutral blocks” to be installed that might have a different configuration of terminals. For example some terminals may be designed to take 4/0 conductor and some may be designed for #4-#14. These neutral blocks may be installed in the field on a case-by-case basis, depending on the requirements of the installer.

### C. PCM and Gateway

C.1 Panel-to-Panel or Panel-to-Appliance Communications Through PLC (Power Line Communications) and RF Communication with a (E.g., 915 Mhz) Antenna.

Description: Send data through AC power lines for data transmission. As a fallback, uses a Sub-Gig antenna for data transmission.

Solution for: Data transmission without the using internet or ethernet connection. Uses the wires in the wall already. Or if it is not possible to run hardwired communication lines due to long distances or noise on the power line, the Sub-Gig antenna works more effectively through walls and longer distances.

Traditional electrical panels don't communicate data from panel-to-panel.

Cloud based connection common for comms. This allows for communication when connection to the cloud cuts out.

C.2 UI Bar has User-accessible Panel Reset and Control Buttons. The UI Bar Provides Information on the Health of the Panel.

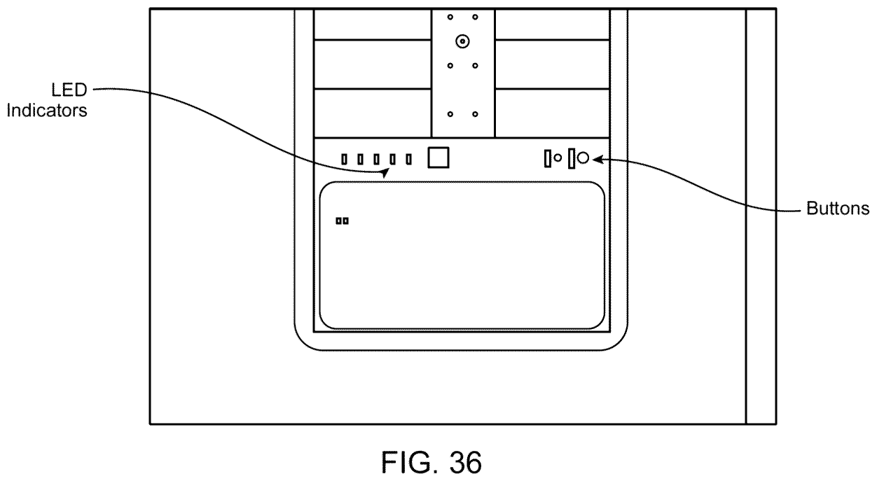

Description: Ability for a panel to be reset with a button and allow installers and homeowners to diagnose panel faults and respond adequately. This can be related to poor connection, power outages, or connectivity issues. For example, see FIG. 36.

Solution for: Smart panels can occasionally have faults or there is a need to reset the panel software. The homeowner can activate the reset button without an installer being onsite. In some instances, permission is needed from the homeowner to take an action on the panel that could impact the home. A physical button requires the customer to be present in the home and gives them override ability and control over their panel.

User-resettable buttons and fault/performance indicators are new for this class of product.

Status LEDs and a reset button may be useful physical interfaces for a smart, power distribution panel.

C.3 User-serviceable Gateway that Can be Used in Any Span Panel, Future Iterations of the Panel, or Products that Require Either Load/source Sense and/or Actuation.

Description: The Gateway contains edge compute algorithms for energy management and is responsible for connecting the panel with the cloud via wireless technologies. It can be placed in or across multiple products within the product family. The same module can be placed into many products across the home (e.g., selecting the location with the best Wifi/cellular connection). If a home include multiple panels, a single gateway may be used. One construction item shown in the future is used of the connector carriage. This holds the connectors in place when they have been removed by the user to swap out the gateway.

Solution for: Cost savings for a single gateway across a smart electric home. Getting the best connection to the router/cellular network that is possible in a given home configuration. Ability to swap in new gateway periodically (e.g., 15 years down the road when technology or compute is improved).

Provides shared use of a single compute module within a panel across multiple products within a home. Enables a reduced-cost option for upgradability for future compute needs without replacing the entire panel.

Takes advantage of the smart electrified home by combining functionality for external comms into a removable gateway and internal comms inside of the panel product itself.

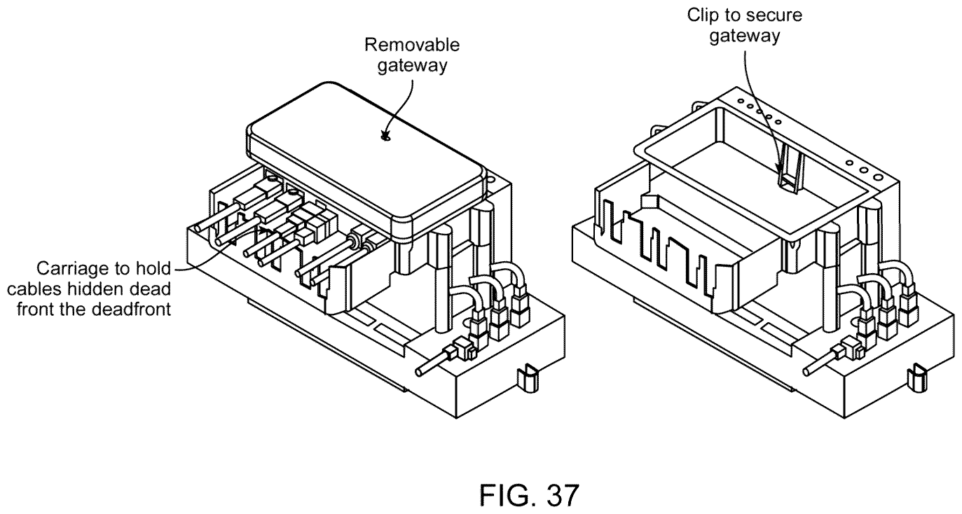

An example gateway module is illustrated in FIG. 37.

### C.4 Internal Antennas for Aesthetic Design, but Provision for External Antennas

Description: The antenna network goes through an external Fakra connector. This allows the same radio to be used with an external antenna (can be a large antenna in an enclosure that lives outside of the system). For a small number of homes where the internal antennas are not sufficient, the external antennas can be a reliable fallback.

User connections are made easy through the use of the gateway carriage.

Internal and external antennas usually not on the same radio when existing in separate physical units.

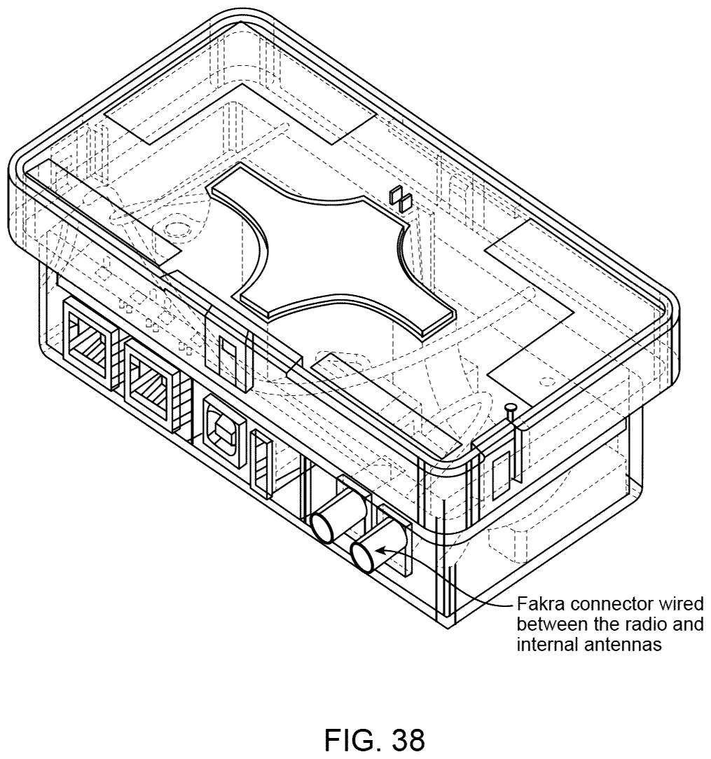

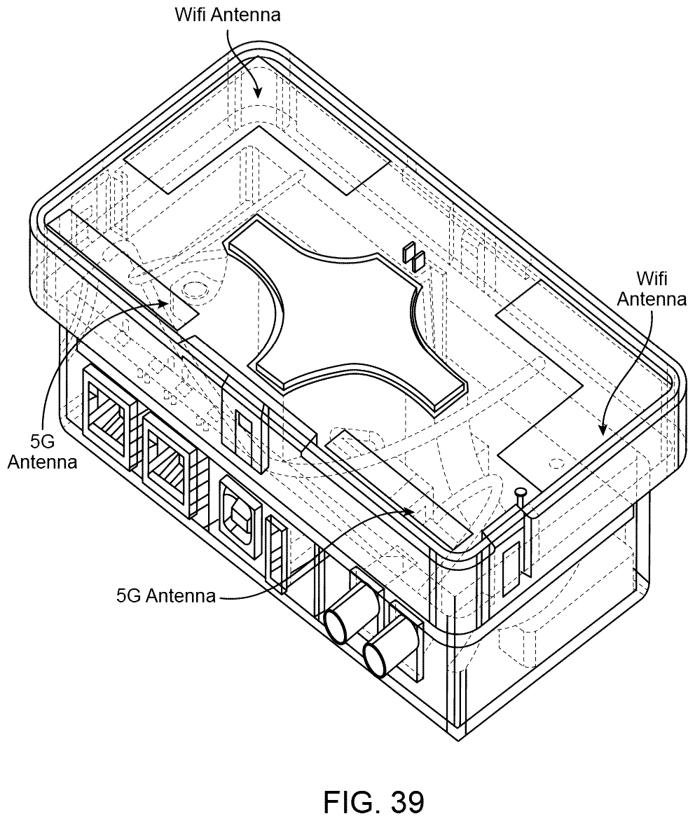

An example antenna in a gateway module is illustrated in FIGS. 38-39.

### C.5 Antenna Performance Design Features.

Description: Antennas do not perform well behind metal dead fronts. Thus, embodiments enable antenna performance in three ways:

Antennas are included in the gateway so that the antennas can hover proud of the dead front through a cutout in the sheet metal.

The panel uses a plastic door which is RF-transparent and allows the antennas to radiate out with a direct “line of sight” to over 180° through the plastics.

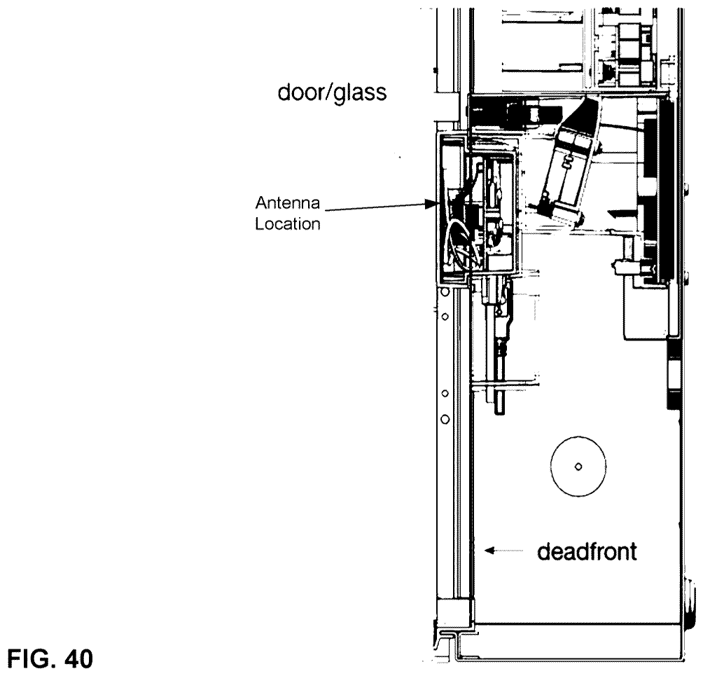

The plastic door has cutouts in it that are covered by glass, which allows the gateway to sit as close to the glass for improved (e.g., best) performance (to get an additional 5° line of sight above the 180 from just being at deadfront level). For example, see FIG. 40.

Usually external antennas on existing panels are puck antennas on the sides of the panel outside the metal. This hovers in front of the metal with a plastic door.

### C.6 Future Proof the Connectivity of Upcoming New Distributed Energy Resources

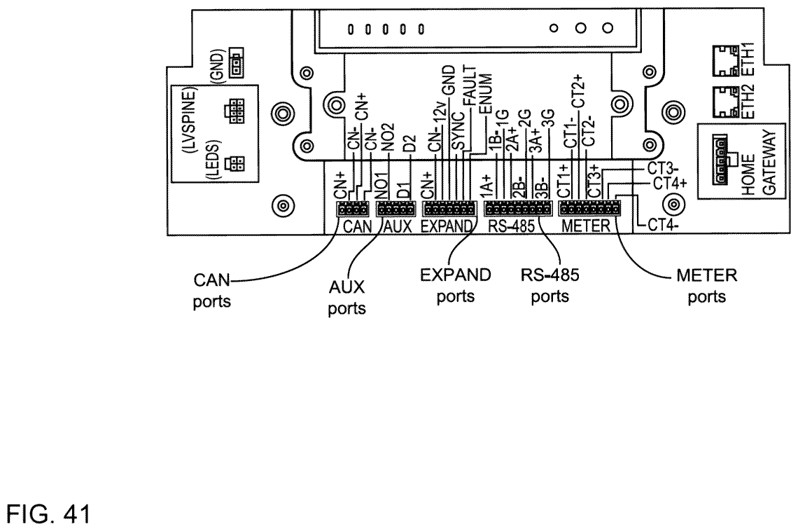

Description: Provisions for connecting power and communications to external distributed energy resources and modules. The Expand port (indicated in FIG. 41) allows for connection to the same spine CAN bus that serves internal modules (e.g., on a different bus with it's own enumeration chain).

### D. Mains

### D.1 MID/Main Breaker Configurations

Description: Main Breaker and Grid Disconnect architecture enables lower-cost configurations.

Some existing panels always come with an MID (grid disconnect component) and a Main breaker. However, some homes only need the MID, or the main breaker, or both, or neither. These different configurations are either not available or must be configured at the factory only. They cannot be swapped in the field in existing smart panels.

Shared parts can be used for a single module which can include a main breaker or no main breaker, and a Grid disconnection and no grid disconnect feature.

### D.2 Completely Modular Main Breaker, Grid Disconnect, and Branch Module Construction Enabled by a HV and LV Distributed Construction

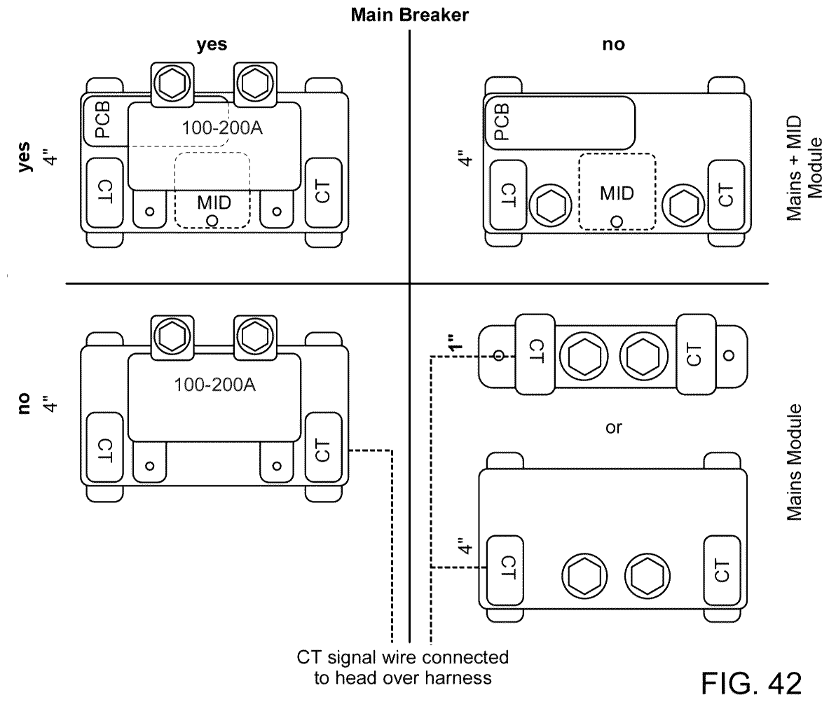

Description: Some embodiments enable the ability to remove the MID and/or Main Breaker functionality and add additional branch modules (e.g., up to 6). Alternatively, with the inclusion of the Main Breaker and grid disconnect, the panel may include fewer branch modules (e.g., up to 5). For example, see FIG. 42.

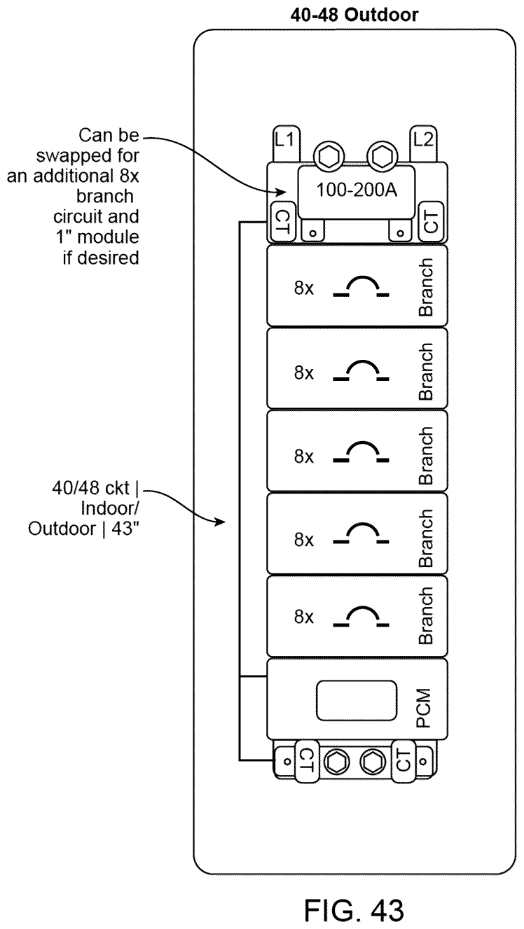

If there is no Mains module, additional branch circuits (e.g., 8 branch circuits) may be added to the panel as desired. For example, see FIG. 43.

Traditionally, adding additional branch circuits requires a separate panel that has a larger number of circuits or a main breaker/grid disconnect functionality. However, panel embodiments described herein may allow for the installer to place the main breaker/Grid disconnect or additional branch modules in the field.

D.3 Removable Fan Kit with Blower Fans

Description: Fan module as pictured below. The fan module can be easily removed/replaced, or not included if not needed (in cool indoor environment).

Hot climates and rising global temperatures may require additional cooling; this is an initial cost saver for customers with the ability to pay for the feature only when desired.

Fans typically do not have 30 years of lifetime in many cases due to the moving parts. The removable fan kit allows for easy replacement and only needs to be included when necessary.

An example fan module is illustrated FIG. 7C. An example fan module in a PCM is illustrated in FIG. 7A.

### D.4 Heatsink in Grid Disconnect Bussing.

Description: Integrating heat sinks into the Main breaker to MID bussing. The MID bussing has integrated heat sinks which allow for convection across a high power loss bus. Moreover, this does not contribute to Joule heating/Ohmic losses due to the heatsink being out of the current path for this bus.

Other panels do not provide heatsinks in line between the Main breaker and MID integrated into the bussing.

Solution for: Thermals

Some embodiments may include an optional fan (e.g., a removable fans), however a fan may not be required. For example, a fan isn't used indoors where the ambient temps are lower and there is now solar irradiation. Also, the fan noise may be more bothersome to users in indoor installations. The combination of those two items makes a removable fan ideal for some indoor situations.

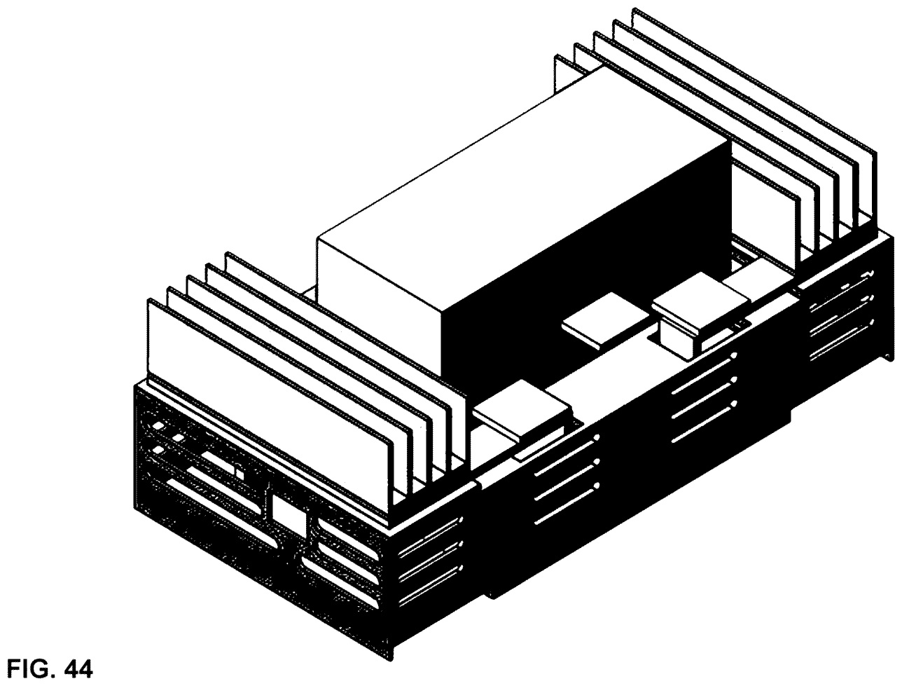

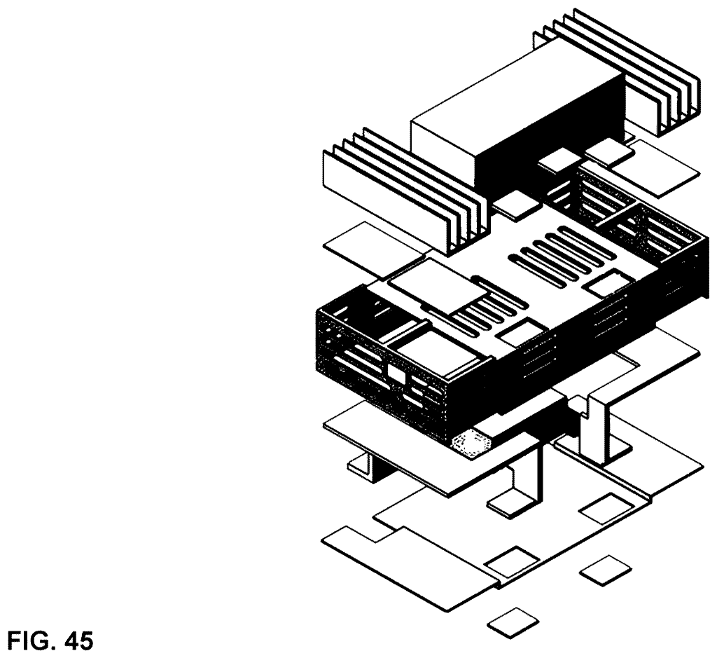

Example heat sinks are illustrated in FIGS. 44-45.

### E. Standalone Gateway

Generally, the PCM (Panel Control Module) and Gateway (both previously described) may collectively be referred to as a “site controller.”

A standalone gateway (also referred to as a standalone site controller) may include (e.g., all) elements from the PCM and the Gateway (previously described). The standalone gateway may be fitted into a custom enclosure with relevant I/O, that can act as a site controller for products (e.g., without a panel including this functionality).

The standalone site controlled may be a product that is not a part of an electrical panel. It may contain the functionality roughly equivalent to the PCM and the Gateway. It may have its own custom PCBs and form-factor. It may be a product that receives the removable gateway and powers it. The standalone site controller may enable whole-home monitoring, 3rd party integrations, and/or dynamic load management without a SPAN electrical panel (e.g., the panels described above).

For example, a user wants to use a Span EVSE car charger or some other Span product that typically interacts with a Span electrical panel for energy monitoring and that cannot communicate with the cloud on its own. If the user does not want to upgrade their electrical panel to be a Span electrical panel, they wouldn't benefit as much from the EVSE car charger (or other product). However, if the user has a site controller, they may be able get increased functionality (e.g., the full functionality) from this device. Span products may interact with the site controller with the same panel-to-panel and panel-to-appliance communication protocols described in C.1.

Some embodiment of the standalone site controller are further described below.

### E.1 Standalone Site Controller and Meter

Description: Packaging the Panel Control Module (PCM), Gateway, and Remote Meter in a standalone configuration to enable whole home monitoring, 3rd party integrations, and dynamic load management without a panel replacement and upgrade.

Other panels do not have compute modules. While this module may use repackaging and depopulation of features and connection not needed for the site controller, it starts with the same architectural design. This enables SPAN integration and SW control and monitoring for electric home products like battery systems, HVAC and thermostat control, EV charging load management, without the need for a SPAN panel.

The details of the standalone site controller design may or may not be exactly like the head module and gateway. In some embodiments, the PCB does not include all the functionality of the PCM. The plastic enclosure shape of the standalone site controller may also be different than as illustrated. The gateway PCB and plastics may remain the same in the standalone site controller. With these changes, the standalone site controller may maintain the features and functionality of the PCM for SPAN integration and SW control and monitoring for electric home products like battery systems, HVAC and thermostat control, EV charging load management without the need for a SPAN panel.

Among other advantages, embodiments provide differentiated whole-home integrations and feature sets without a panel replacement. Additionally, embodiments may be capable of local comms with battery systems, HVAC and thermostat control, EV charging load management.

### F. Whole Panel

F.1 Branches and Subsequently Added Modules Will Know Where They are in the Panel Even with Flipping due to Enumeration Scheme.

Description: The orientation of the panel is determined by a tilt sensor or accelerometer (or may be input into the app by the installer). Thus, the panel may provide automatic detection of the flipped panel backplate. The branch positions may be determined using a resistor ladder which helps to number the modules so that branch circuit positions across the modules are known.

Solution for: Correlation of circuit positions in the breaker (numbered on the deadfront), to the app without special assignment by installer. When a new module is swapped in, the system may determine its position automatically. This enables significantly quicker install when the main wiring is bottom-fed.

Among other advantages, this enables the ability to flip the internals of the panel and accommodate top or bottom entry of feeder wiring (e.g., by either swapping Lug module positions or flipping the entire backplate to ease installation). Furthermore, using jumpers requires no termination resistor.

### F.2 Internal Energy Storage

Description: Distributed energy storage allows for subsystems to fulfill duties. Relay actuation is possible when other components in the system fail. Embodiments may be implemented on a module by module basis to help ensure one or more modules can fail safe on its own and one module doesn't bring down the whole system. Among other advantages, use of distributed capacitance allows for overall capacitance to be reduced

Solution for: Voltage sags from the grid and disruption of AC due to poor bolted joint connections can fail safe.

F.3 Vented Deadfront with Possible Forced Convective Heat Transfer

Description: An electrical panel including a deadfront where certain embodiments may include vents, slots, or a mesh in the primary deadfront surface to facilitate additional heat transfer to the ambient environment. Some embodiments may also include fans to increase the panels ability to reject internal heat due to convective heat transfer to the ambient environment. Some embodiments may use the deadfront as a “duct” or “plenum” to isolate airflow paths and transfer more heat to the ambient environment.

Differences over existing panels: Deadfront is typically only a protection barrier. While there may be unintentional openings around the perimeter of the deadfront due to loose fit, no panel has dedicated venting for airflow from the hot air behind the deadfront to the colder air in front of the deadfront to cycle.

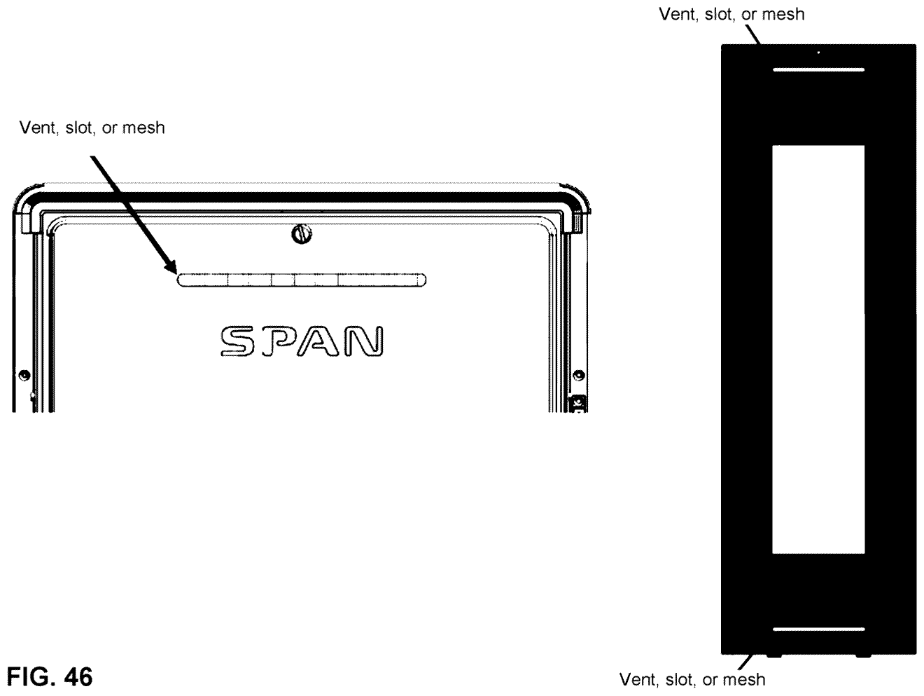

FIG. 46 illustrate example deadfront surface panels. The arrows indicate example vents, slots, or mesh.

### Additional Considerations

Other aspects from the above descriptions and sections include components,

devices, systems, improvements, methods, processes, applications, computer readable mediums, and other technologies related to any of the above.

Although the detailed description contains many specifics, these should not be construed as limiting the scope of the invention but merely as illustrating different examples. It should be appreciated that the scope of the disclosure includes other embodiments not discussed in detail above. Various other modifications, changes and variations which will be apparent to those skilled in the art may be made in the arrangement, operation and details of the apparatus disclosed herein without departing from the spirit and scope as defined in the appended claims. Therefore, the scope of the invention should be determined by the appended claims and their legal equivalents.

In the claims, reference to an element in the singular is not intended to mean “one and only one” unless explicitly stated, but rather is meant to mean “one or more.” In addition, it is not necessary for a device to address every problem that is solvable by different embodiments of the invention in order to be encompassed by the claims.

The term “coupling” is not meant to exclude intervening elements. For example, when two elements are described as being coupled to each other, this does not imply that the elements are directly coupled to each other nor does it preclude the use of other elements between the two.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

What is claimed is:

1. A chassis module for a chassis, the chassis module comprising:
an insertion element configured to slide into one of a plurality of receiving compartments of a spine of the chassis, the insertion element comprising:
a first electrical contact on a first side of the insertion element and configured to physically contact a first bus bar of the spine; and
a second electrical contact on a second side of the insertion element opposite the first side, the second electrical contact configured to contact a second bus bar of the spine.

2. The chassis module of claim 1, wherein the chassis is an electrical panel, and the chassis module is an electrical component for the electrical panel.

3. The chassis module of claim 1, further comprising a port for attachment of a data and/or power connection to the chassis module.

4. The chassis module of claim 3, wherein the port is accessible for attachment of the data and/or power connection after the chassis module is at the receiving compartment.

5. The chassis module of claim 1, further comprising a first portion on the first side of the insertion element, the first portion including the first electrical contact, the first portion configured to receive the first bus bar of the spine and directly couple to the first bus bar.

6. The chassis module of claim 5, further comprising a second portion on the second side of the insertion element, the second portion including the second electrical contact, the second portion configured to receive the second bus bar of the spine and directly couple to the second bus bar.

7. The chassis module of claim 6, wherein the insertion element further comprises a third portion between the first portion and the second portion, the third portion configured to, when the insertion element is in one of the plurality of receiving compartments, be between the first bus bar and the second bus bar of the spine.

8. The chassis module of claim 1, wherein the first electrical contact is arranged to physically contact a top surface of the first bus bar of the spine when the insertion element is in one of the plurality of receiving compartments.

9. The chassis module of claim 1, wherein the insertion element further comprises:
a track indentation configured to engage with a guiding structure of the spine (a) to guide placement of the insertion element into one of the plurality of receiving compartments and (b) to retain the insertion element in the one of the plurality of receiving compartments after placement.

10. The chassis module of claim 9, wherein the track indentation extends along a sliding direction of the receiving compartment.

11. The chassis module of claim 9, wherein the insertion element includes a plurality of track indentations including the track indentation.

12. The chassis module of claim 9, wherein the track indentation is part of an outer surface of the insertion element.

13. The chassis module of claim 6, wherein the first portion and the second portion each form a hole configured to receive a fastener that fastens the insertion element to the respective bus bar.

14. The chassis module of claim 1, wherein the insertion element further comprises:
a first clip mechanism on the first side of the insertion element, the first clip mechanism configured to engage with a first portion of the spine to hold the first electrical contact in physical contact to the first bus bar; and
a second clip mechanism on the second side of the insertion element, the second clip mechanism configured to engage with a second portion of the spine to hold the second electrical contact in physical contact to the first bus bar.

15. The chassis module of claim 1, wherein the insertion element further comprises:
a first protrusion on the first side of the insertion element, the first protrusion configured to engage with a first clip mechanism of the spine to hold the first electrical contact in physical contact to the first bus bar; and
a second protrusion on the second side of the insertion element, the second protrusion configured to engage with a second clip mechanism of the spine to hold the second electrical contact in physical contact to the second bus bar.

16. The chassis module of claim 1, wherein:
the chassis is an electrical panel;
the chassis module is an electrical component for the electrical panel; and
the chassis module is a mains module that connects main feeder wires to the electrical panel.

17. The chassis module of claim 16, wherein the mains module comprises at least one of:
a main breaker for the electrical panel; or a microgrid interconnection device.

18. The chassis module of claim 16, wherein the mains module is configured to provide overcurrent protection and a disconnect for the electrical panel.

19. A chassis module for a chassis, the chassis module comprising:
an insertion element configured to slide into one of a plurality of receiving compartments of a spine of the chassis, the insertion element comprising:
a first electrical contact on a first side of the insertion element and configured to physically contact a first bus bar of the spine,
wherein the first side of the insertion element forms a first hole configured to receive a first fastener that holds the first electrical contact in physical contact to the first bus bar; and
a second electrical contact on a second side of the insertion element opposite the first side, the second electrical contact configured to contact a second bus bar of the spine;
wherein the second side of the insertion element forms a second hole configured to receive a second fastener that holds the second electrical contact in physical contact to the second bus bar.

20. A chassis module configured for installation at any of a plurality of receiving compartments of a spine of a chassis, the spine comprising two bus bars, the chassis module comprising:
two bus bar contacts on a bottom of the chassis module, where each of the two bus bar contacts physically contact the corresponding bus bar of the spine, and the bus bar contacts and the bus bars have hole patterns for attachment of the chassis module to the spine at the receiving compartment; and
a port for attachment of a data and/or power connection to the chassis module.
